(19) United States
(12) Patent Application Publication
(10) Pub. No.: US 2023/0330619 A1
(43) Pub. Date: Oct. 19, 2023

(54) Methods and Apparatus for Plasma Processing

(71) Applicant: Haydale Graphene Industries PLC, Carmarthenshire, South Wales (GB)

(72) Inventors: John-Mark Seymour, Carmarthenshire, South Wales (GB); Thomas Howe, Carmarthenshire, South Wales (GB)

(21) Appl. No.: 18/027,079

(22) PCT Filed: Sep. 17, 2021
(86) PCT No.: PCT/EP2021/075691

§ 371 Date: Mar. 17, 2023

(30) Foreign Application Priority Data
Sep. 18, 2020 (GB) 2014776.5
Sep. 18, 2020 (GB) 2014779.9

(51) Int. Cl. B01J 19/08; C01B 32/194; C01B 32/198; C01B 32/174; C01B 32/21; C01B 21/064; H01J 37/32

(52) U.S. Cl. CPC B01J 19/088; C01B 32/194; C01B 32/198; C01B 32/174; C01B 32/21; C01B 21/0648; H01J 37/32036; H01J 37/32477; H01J 37/32522; H01J 37/32944; C01B 2202/06; B01J 2219/0896; B01J 2219/0847; B01J 2219/0809; B01J 2219/0879; H01J 2237/2001

(57) ABSTRACT

The present invention relates to a method for treating a sample using glow-discharge plasma, in an apparatus comprising a treatment vessel, an electrode, a counter-electrode, and a power supply comprising one or more transformers and having a first transformer setting and a second transformer setting, the method comprising: (i) a loading step, involving loading the sample into the treatment vessel; (ii) a first treatment step involving treating the sample in a glow-discharge plasma formed within the treatment vessel by applying an electric field between the electrode and counter-electrode at the first transformer setting; (iii) a second treatment step involving treating the sample in a glow-discharge plasma formed within the treatment vessel by applying an electric field between the electrode and counter-electrode at the second transformer setting; and (iv) a removal step, involving removing treated sample from the treatment vessel. The method can be used to functionalize a sample. The present invention also relates to an apparatus for use in such a method.

### FIELD OF THE INVENTION

This invention has to do with methods and apparatus for plasma treatment of a range of materials, in particular, methods for plasma treatment of particles, for example carbon particles such as graphitic particles and graphene platelets.

### BACKGROUND: PLASMA TREATMENT

Glow discharge plasma treatment is a method which can be used to treat a wide range of materials. This includes the treatment of particulate materials, as disclosed in our own earlier patent applications WO 2010/142953 and WO 2012/076853.

In order to efficiently treat a material with glow discharge plasma, it is generally necessary to operate plasma treatment for sustained periods of time under closely controlled low-pressure conditions. However, there are a number of issues which can complicate this.

Firstly, glow discharge systems are prone to the formation of electrical arcs, caused by an electrical discharge occurring along a path of lower resistance than a path through the plasma field. Such arcs can cause serious damage to plasma-generating apparatus and treatment sample. Furthermore, they disrupt plasma production, and therefore lead to reduced control of surface treatment.

The problems caused by electrical arcs are particularly problematic in instances where it is desirable to carry out sequential treatment (e.g. functionalisation) of a material's surface with different feedstock gases, because arc formation is dependent on the dielectric strength of the gas. Therefore, typical plasma treatment apparatus are configured to operate with a single gas or gas mixture per treatment run, with the gas(es) selected from a limited range of gases which are compatible with the characteristics of the apparatus. For example, the apparatus may be configured to form plasmas from oxygen or air, but unable to form plasma using CF₄ as the sole feedstock. Treatment with incompatible gases may be impossible (due to the inability to form and maintain a plasma) or, if possible, can lead to damage of the machine.

Furthermore, the desire to avoid arcing can limit the amount of power which can be supplied to drive plasma formation, since higher power levels increase the risk of arcing.

Such issues can be exacerbated by changes in pressure conditions within the plasma treatment chamber, since increases in pressure will eventually prevent formation of a stable plasma, and will increase the propensity for arcs to form. Problems arising from changes in pressure are a particular concern for plasma processing of particulate material, as described in WO 2010/142953 and WO 2012/076853, due to the need to incorporate filter elements to keep particles in a treatment vessel and prevent them from being sucked into the vacuum system. Additionally, particles or fines can be produced as a result of agitation during the treatment process. These filters can become blocked by particulate material over time, changing pressure characteristics. This issue can become so problematic that the machine must be temporarily shut down, to clean or replace blocked filters.

Another issue arising from long processing times is that the sample being treated can become hot during processing, for example, due to heat generated by powering the electrical equipment. This problem can also be significant in plasma systems which agitate particulate material during processing, due to the action of friction between the particles. Such heating can degrade the sample being treated, and alter the efficiency of the treatment.

Accordingly, there is a need to provide more efficient plasma treatment apparatus and methods, suitable for reliable and sustained treatment of a wider variety of materials with a wide variety of plasma feedstocks.

### SUMMARY OF THE INVENTION

Advanced Generator System/Multi Transformer System

In view of the above problems, in a first aspect, the present invention provides a method for treating a sample using glow-discharge plasma, in an apparatus comprising a treatment vessel, an electrode, a counter-electrode, and a power supply comprising one or more transformers and having a first transformer setting and a second transformer setting, the method comprising:
a loading step, involving loading the sample into the treatment vessel;
a first treatment step involving treating the sample in a glow-discharge plasma formed within the treatment vessel by applying an electric field between the electrode and counter-electrode at the first transformer setting;
a second treatment step involving treating the sample in a glow-discharge plasma formed within the treatment vessel by applying an electric field between the electrode and counter-electrode at the second transformer setting; and
a removal step, involving removing treated sample from the treatment vessel.

Advantageously, switching between transformer settings alters the electric field between the electrode and counter-electrode, and hence can be used to change the nature of the plasma. This means that the transformer settings can be tailored to the particular conditions present during the first and second treatment steps, so as to form stable plasma at a desired power.

The method is especially useful when the plasma-forming feedstock is changed from the first and second treatment steps. Specifically, the transformer settings can be chosen to both generate and maintain a stable plasma using a wide range of different feedstocks, in a way that is not possible using known machines. This opens up the possibility of treating with feedstocks having different properties in a single treatment run, expanding the range of treatments possible. For example, the method may involve a first treatment step using a gas which has a relatively low dielectric strength, and a second treatment step using a gas which has a relatively high dielectric strength. The method is especially useful for functionalisation of particles, since the method may be used to achieve multi-step functionalisation processes in a way not possible previously.

More generally, the method is useful when there is a change in the type of treatment being applied and/or the treatment conditions between the first and second treatment step, such as a change in the pressure in the treatment vessel.

Being able to change the transformer setting between treatment steps minimises and can potentially eliminate the occurrence of arcs during treatment, which helps to prevent damage to the plasma-forming apparatus. Furthermore, in apparatus incorporating an arc detection system (discussed below), changing between transformer settings can be used to minimise the occurrence of phantom arcs. By “phantom arcs” we mean electrical events which are identified as arcs by the arc detection system but which are, in fact, not arcs.

Suitably, switching between the first and second transformer settings occurs during operation of the apparatus. By “during operation of the apparatus” we mean that the apparatus is not shut down during switching between transformer settings. In other words, the treatment method is a continuous process. This allows the sample to be retained in the treatment vessel between the first and second treatment steps.

The first and second transformer settings may have voltage ratios (defined as the primary voltage rating divided by the secondary voltage rating at no load) of, for example, 0.5 or less, 0.45 or less, 0.4 or less, 0.35 or less, 0.3 or less, 0.25 or less, 0.2 or less, 0.15 or less, 0.1 or less, 0.05 or less, 0.025 or less, or 0.01 or less.

Preferably, the first and second transformer settings have different voltage ratios. Thus, the first and second transformer settings may correspond to transformer settings having different secondary voltage ratings. For example, the difference between the first and second transformer voltage ratios may be at least 0.01, at least 0.025, at least 0.05, at least 0.1, at least 0.15, at least 0.2, at least 0.25, at least 0.3, at least 0.35, at least 0.4, at least 0.45, or at least 0.5. In this way, for a given input voltage, switching between the first and second transformer settings will lead to a different voltage being developed at the electrode.

The secondary voltage ratings of the first and second transformer settings may be, for example, 100 V or more, 200 V or more, 300 V or more, 400 V or more, 500 V or more, 750 V or more, 1 kV or more, 1.5 kV or more, 2.0 kV or more, 2.5 kV or more, 3.0 kV or more, 5.0 kV or more, 10.0 kV or more or 15.0 kV or more. The first and second transformer settings may correspond to transformer settings having different secondary voltage ratings. For example, the first transformer setting may be a relatively lower secondary voltage rating and the second transformer setting may be a relatively higher secondary voltage rating, or vice versa.

The difference between the secondary voltage rating of the first and second transformer settings may be at least 100 V, at least 200 V, at least 300 V, at least 400 V, at least 500 V, at least 750 V, at least 1 kV, at least 1.5 kV, at least 2.0 kV, at least 2.5 kV, at least 3.0 kV, at least 4.0 kV, at least 5 kV, or at least 10 kV. The upper limit for the difference between the secondary voltage rating of the first and second transformer settings may be, for example, 5.0 kV, 3.0 kV, 2.5 kV, 2.0 kV, 1.5 kV, 1.0 kV or 500 V. For example, the difference between the secondary voltage rating of the first and second transformer settings may be between 100 V to 3.0 kV, 100 V to 2.0 kV, or 500 V to 2.0 kV.

The power supplied by the power supply may remain the same during the first treatment step and second treatment step. Alternatively, the method may involve changing the power supplied by the power supply between the first treatment step and the second treatment step. To this end, the method optionally includes the step of the user selecting the desired power (Watts) to be supplied to the electrode during the first and/or second treatment step. For example, the first treatment step may be a relatively low power “gentle” treatment (say, at 70 W power) and the second treatment step may be a relatively higher power “aggressive” treatment (say, at 2000 W). Optionally, the power is also modulated during the course of a treatment step, as described in greater detail below.

The present inventors have discovered that the peak voltage measured at the electrode during maintenance of the glow-discharge plasma at the desired power level (i.e. the voltage developed upon application of a load), expressed as a percentage of the secondary voltage rating at no load (i.e. the nameplate secondary voltage rating), provides a good measure of the performance of the transformer setting. This measure is referred to herein as the “voltage rating percentage”. Specifically, they have found that when the voltage rating percentage required to achieve the desired power level is of the order of 80-95%, the apparatus forms an even, stable plasma with minimal or no formation of arcs. In contrast, voltage rating percentages at ˜100% lead to flickering of the plasma, as the power supply struggles to achieve the desired power at the electrode. Similarly, voltage rating percentages of below 80% also cause the power supply to have difficulty in supplying the required power levels. In certain instances, the power supply may decrease the frequency of the supplied AC power supply in order to supply the required power level, which leads to further inefficiency in the voltage conversion provided by the transformer setting.

The first and second transformer settings may have volt-ampere (kVA) output power ratings of, for example, at least 0.2 kVA, at least 0.5 kVA, at least 1.0 kVA, at least 1.5 kVA, at least 2.0 kVA, at least 2.5 kVA, at least 3.0 kVA, at least 4.0 kVA, at least 5 kVA, at least 8 kVA, at least 10 kVA, at least 15 kVA, at least 25 kVA, at least 50 kVA, at least 100 kVA, at least 250 kVA, or at least 500 kVA.

The first and second transformer settings may correspond to transformer settings having different volt-ampere (kVA) output power ratings. For example, the first transformer setting may be a relatively lower kVA output power rating and the second transformer setting may be a relatively higher kVA output power rating. The difference between the kVA output power ratings of the first and second transformer settings may be, for example, at least 0.2 kVA, at least 0.5 kVA, at least 1.0 kVA, at least 1.5 kVA, at least 2.0 kVA, at least 2.5 kVA, at least 3.0 kVA, at least 4.0 kVA, at least 5.0 kVA, at least 8.0 kVA, at least 10 kVA, at least 15 kVA, at least 25 kVA, at least 50 kVA, at least 100 kVA, or at least 250 kVA.

Preferably, switching between the first and second transformer settings occurs according to a pre-set program. For example, the program may be configured to switch between the first and second transformers in response to processing parameters, such as elapsed time, pressure in the treatment vessel or, preferably, in response to a change in the plasma-forming feedstock. Preferably, the switching between the first and second transformer settings is automated.

The first and second transformer settings may correspond to use of the power supply with first and second transformers respectively. In such instances, the first treatment step involves generating a glow-discharge plasma using a first transformer, and the second treatment step involves generating a glow-discharge plasma using a second transformer, wherein the first transformer and second transformer have different characteristics, such as a different voltage ratio, secondary voltage and/or volt-ampere power output rating.

For example, the secondary voltage rating of the first transformer may be lower than the secondary voltage rating of the second transformer. Alternatively, the secondary voltage rating of the first transformer may be higher than the secondary voltage rating of the second transformer. The first and second transformers may have any of the voltage ratios, secondary voltage ratings and volt-ampere power ratings specified above.

Alternatively, the first and second transformer settings may correspond to switching between different settings on a single transformer. For example, the settings may correspond to switching between taps on a single transformer. Such a transformer may have, for example, 2, 3, 4, 5, 6, 7, 8, 9, 10, 15, or 20 taps to produce different voltage ratio ratings. For example, the transformer may have 2, 3, 4, 5, 6, 7, 8, 9, 10, 15, or 20 taps on the secondary coil in order to produce different secondary voltages.

For the avoidance of doubt, the terms “first” and “second” used in relation to the treatment steps indicate the sequence of those steps relative to one another, and do not exclude the possibility of other steps taking place before, between, and/or after. There may be no intervening steps between the first and second treatment steps.

The first and second treatment steps may be the only treatment steps used during the treatment method. Alternatively, the treatment method may involve further treatment steps, such as a third treatment step, fourth treatment step, fifth treatment step, or sixth treatment step.

Power Levels

The plasma treatment is by means of low-pressure plasma of the “glow discharge” type, usually using low-frequency RF (less than 100 kHz) AC. Most preferably, the plasma is formed at a frequency below 100 kHz, such as between 25-35 kHz.

Optionally, the power supplied from the power supply during at least one treatment step (optionally all treatment steps) is modulated periodically between a higher power level and a lower (or no) power level. In particular, the present inventors have found that modulating the power levels so that high power levels are only used for a short period, boosts the level of sample treatment, whilst reducing the risk of arcing compared to running continuously at the same power level. This is particularly useful, when treating materials that are conductive or require high powers in order to effect treatment (e.g. functionalisation). Without wishing to be bound by any theory it is believed that modulating the power levels reduces the chance of the plasma stabilising, meaning that with each modulation potential arcing sites are eliminated.

This modulation of power levels during a treatment step should be distinguished from switching between a first transformer setting and a second transformer setting between different treatment steps. The former occurs at the same transformer setting. In addition, the former necessitates a change in the power supplied to the electrode(s), whereas the latter does not.

The power may be modulated between the higher and lower levels periodically according to a set pattern. The pattern may have any suitable waveform, for example, a sine wave, a square wave, a triangular wave or a saw tooth wave. The frequency at which the pattern repeats may be at least 1/60 Hz (one cycle per minute), at least 1/30 Hz, at least 1/10 Hz, at least 1 Hz, at least 2 Hz, at least 10 Hz, at least 20 Hz, at least 100 Hz, or at least 500 Hz. The frequency of repetition may optionally be less than 1000 Hz, or less than 500 Hz such as for example, from 1/60 Hz to 100 Hz.

The power (in Watts) of the lower power level may be no more than 90% of the higher power level, no more than 80% of the higher power level, no more than 70% of the higher power level, no more than 60% of the higher power level, or no more than 50% of the higher power level.

The lower power level may be at least 10%, at least 20%, at least 30%, at least 40% or at least 50% of the higher power level.

In instances where the power is modulated periodically according to a set pattern, the lower power level may correspond to supplying no power (note that this is different to an arc detection apparatus turning off the machine, since in such instances shutting off of the power does not occur according to a pre-set pattern). In other words, modulation of the power level may involve switching between >0 Watts and 0 Watts.

The higher and lower power levels may vary within ±10%, ±20%, ±30%, or ±40% of the mean power level (the mean calculated as half of the sum of the maximum and minimum power levels).

In instances where the set pattern is a square waveform, the time spent at the higher power level may be equal to that spent at the lower power level. Alternatively, for square waveforms the ratio of time spent at the higher power level compared to the lower power level may be, no more than 0.8, no more than 0.6, no more than 0.4, no more than 0.3, no more than 0.2, or no more than 0.1, when expressed as a fraction (that is, time spent at the higher power level divided by time spent at the lower power level). Alternatively, the ratio of time spent at the higher power level compared to the lower power level may be, at least 1.2, at least 1.5, at least 2.0, at least 3, at least 4, or at least 5.

The higher and lower power levels are determined based on the values measured directly from the power supply.

The power may be modulated in this manner for the whole of a given treatment step; alternatively the power may be modulated for only part of a given treatment step. For example, the power may be modulated at the beginning of a treatment step, in order to functionalize a material at higher power, but then treated at a different power level at the end of the treatment step.

Preferably, the power is modulated during a treatment step between >0 W (the higher power level) and 0 W (lower power level) at a frequency of from 500 Hz to 1000 Hz. Preferably, the ratio of time spent at the higher power level compared to the lower power level is at least 1.

For samples comprising components that are larger than 1 mm in size it is preferable to modulate the power according to a set pattern at a frequency of from 1/60 Hz to 1 Hz. In contrast, for samples comprising components that are smaller than 1 μm it is preferable to modulate the power according to a set pattern at a frequency of from 1 Hz to 1000 Hz. A faster modulation is preferred as the particle size decreases, because smaller particles generally lead to an increased risk of arc formation.

Although the modulation of the power supply is discussed above as an optional addition to the first aspect of the invention, the advantages provided mean that modulation of the power supply during treatment also constitutes a separate proposal of the invention. Therefore, in an alternative aspect, the present invention provides a method for treating materials using glow-discharge plasma, the method comprising one or more treatment steps, wherein during the one or more treatment steps a glow discharge plasma is formed by supplying power to the treatment apparatus, wherein during at least one treatment step the power is modulated periodically between different power levels according to a set pattern. The preferred power levels, types of variation and frequencies described above, also apply for this particular aspect.

Arc Detection System

Optionally, the apparatus includes an arc detection system. It is desirable to include an arc detection system in order to reduce the risk of arcing during a given treatment step and any consequent damage to the treatment apparatus that may occur. This may also allow the apparatus to be used with a wider range of materials (in particular ultra-conductive materials). Additionally, it may help to improve the reproducibility of the process as arcing may also have an effect on the degree of treatment (e.g. functionalisation) of the sample.

Generally, the arc detection system works by monitoring the power, voltage and/or frequency characteristics of the system. If the arc detection system detects a change in power, voltage and/or frequency outside of a pre-specified range (for example, a voltage spike) it reduces the power level. In some cases, the arc detection system may temporarily shut down the power supply upon a change in power, voltage and/or frequency outside of a pre-specified range.

The upper limit for the pre-specified power range may correspond to 150% of the target power value, or in the case where the power is varied 150% of the high power value. Similarly, the upper limit for the pre-specified voltage range may correspond to 150% of the target voltage value.

The arc detection system may reduce the power level for a period of from 2 to 5 seconds, before increasing the power again to the level required to maintain the desired settings.

In general, the changes in power, voltage and/or frequency which trigger the arc detection system are identifiably different to intentional modulation of the power described above. In particular, the spike caused by arc detection is generally much faster than the modulation frequency.

Advantageously, in implementations involving use of different transformer settings in which the power supply is modulated, the level of arcing can be reduced to such an extent that the arc detection system can be dispensed with entirely. Therefore, optionally, the apparatus does not include an arc detection system, therefore avoiding the expense and upkeep associated with such systems.

The arc detection system can be applied to any of the independent proposals set out herein.

Apparatus

The apparatus used in the methods described above may be of the form described in earlier applications WO 2010/142953 and WO 2012/076853, with any or all of the modifications as set out herein.

Preferably, the treatment vessel takes the form of a drum. The outer wall of the drum is desirably cylindrical, or circular in cross-section. The drum is capped by end plates, front and back. The end plates may be integral to the outer wall of the drum. Alternatively, one or both of the end plates may be removable, so as to serve as a lid or cover for the drum.

Preferably, the electrode extends within the interior of the treatment vessel (e.g. drum) and, optionally, the treatment vessel walls (e.g. drum) acts as the counter-electrode. In such instances, the plasma-forming feedstock may be delivered via said electrode.

Sample Types

The type of sample which can be subjected to treatment using the methods of the present invention is not restricted. The sample may be an organic material or an inorganic material.

For example, the sample may be a carbon material (such as carbon nanotubes, carbon nanorods, or graphitic or graphene platelets, including graphene nanoplatelets), boron nitride, zinc oxide, a nanoclay, a ceramic, a semiconductor material, a polymer or plastics material.

The methods set out herein are particularly well-suited to samples made up of a collection/mixture of small discrete parts. For example, the sample may be a particulate/powdered material, or even a plurality of products (such as polymer or metal components, e.g. washers, nuts and bolts). The methods set out above in which the sample is agitated during use are of particular utility to these samples made up of small discrete parts, since the agitation ensures homogeneous treatment of large volumes of material.

Particulate material may be of any size, from pellets and crumb material (generally on the scale of millimetres, to microparticles (having average sizes in the range of 1 to 1000 μm) or nanoparticles (having average sizes in the range of 1 to 1000 nm).

The present inventors have found the methods set out above to be particularly effective in the treatment of particulate carbon material. These types of material are attractive for use as fillers in polymer composite materials, but generally require modification of their surface chemistry to allow effective dispersal in a matrix material. Thus, it is desirable to tailor the surface chemistry of the materials by adding, altering or removing selected chemical groups to the surface of the materials using the methods of the present invention.

The particulate carbon material being treated may consist of or comprise graphitic carbon, such as mined graphite, which is exfoliated by the treatment. After the treatment the treated material may comprise or consist of discrete graphitic or graphene platelets having a platelet thickness less than 100 nm and a major dimension perpendicular to the thickness which is at least 10 times the thickness. In a preferred embodiment, the particulate carbon material may be GNPs (Graphene nanoplatelets), FLG (few layered graphene) or MWCNTs (Multi walled carbon nanotubes).

According to the present invention, the sample may be loaded into the treatment vessel, with a loading density of from 1 kg/m³-100 kg/m³ or from 5 kg/m³-20 kg/m³, wherein the loading density is defined by the following equation:

$$Loading density = \frac{\text{Mass of material loaded into the treatment vessel}}{\text{Total volume of the treatment vessel}}$$

The volume occupied by the sample may be, for example, no more than 10%, no more than 20% or no more than 30% of the total volume of the treatment vessel.

The volume of the treatment vessel is calculated based on the volume defined by the interior surface of the treatment vessel, and thus includes any space occupied by internal components of the apparatus such as electrodes or the electrode shields discussed below.

Agitation

During a given treatment step the sample is preferably agitated within the treatment vessel (that is, moved within the treatment vessel). Agitating the sample during treatment steps can ensure more homogeneous treatment of the sample, both due to exposing different surfaces of the sample to plasma, and potentially shifting the sample to different regions of the plasma. Agitation is particularly advantageous when the sample is made up of a number of discrete elements, such as small items or particulate material, since it can be used to achieve mixing of the sample.

Suitably, agitation involves moving the treatment vessel so as to cause movement of the sample held within the vessel. This may involve the agitation methods described in WO 2012/076853, including rotating the vessel, or agitating in a linear fashion by oscillating, reciprocating or vibrating motion.

Preferably, agitation is achieved by rotating the treatment vessel relative to a housing.

Optionally, the treatment vessel is continuously rotated in a set direction, as described in WO 2012/076853.

Alternatively, the treatment vessel is rotated in a first direction, and then rotated in the opposite direction about the same axis. For example, the treatment vessel is preferably rotated back and forth through an incomplete turn, which is referred to herein as “rocking”. For example, the treatment vessel may be rotated through a total angle of no more than 180°, no more than 120°, or no more than 90° (the “total angle” corresponding to the full arc subscribed by a set point on the treatment vessel). Preferably, the treatment vessel is rotated through an angle of no more than ±120°, no more than ±90°, no more than ±80°, no more than ±70°, nor more than ±60°, no more than ±50°, no more than ±45° or no more than ±30°, measured relative to the starting position of the treatment vessel. In such instances, when the sample in the treatment vessel is a particulate sample, the rocking motion can cause “folding” of the particles over each other, thereby incorporating the glow discharge plasma into the sample.

The lower limit for the amount through which the vessel is rotated may be, for example, at least ±10°, at least ±20°, at least ±30°, or at least ±45°.

The treatment vessel may be rotated (or rocked) at a frequency of at least 1/12 Hz, at least 1/6 Hz, at least 1/4 Hz or at least 1/3 Hz. The maximum may be, for example, 1 Hz or 2 Hz. When the vessel is rocked, this corresponds to the frequency with which the rocking motion is completed per second. When the treatment vessel is rotated continuously, these figures can be expressed as revolutions per minute (rpm) corresponding to at least 5 rpm, at least 10 rpm, at least 15 rpm, at least 20 rpm, up to a maximum of for example 60 rpm or 120 rpm.

Preferably, the treatment vessel is rotated through an angle of ±90° at a frequency of from 1/6 to 1/2 Hz.

Rotating the treatment vessel alternately between a first direction and its opposite direction can lead to a number of advantages over rotating the vessel continuously in one direction.

In particular, this method of agitation can significantly simplify design of the apparatus, and delivery of components into the treatment vessel.

For example, in instances where the treatment vessel is connected to tubing for feeding a fluid into the treatment vessel (e.g. a plasma forming gas), continuously rotating the barrel in a given direction can complicate delivery of the fluid. Tubing engaging the treatment vessel parallel to the axis of rotation must be coupled via a rotating coupler, or else be wound to occlusion or breaking. If multiple tubing lines are aligned with the axis of rotation, these will also become wound together. Tubing entering across the axis of rotation can become wound around the treatment vessel during rotation. Similar considerations apply to electrical feeds. For example, in the system described in WO 2012/076853 having a cylindrical barrel with an in-built central electrode, provision of power to the central electrode can be complicated when the barrel is rotated continuously—provision through contact with a stationary drive electrode can quickly lead to frictional wear between the electrode and drive electrode.

In contrast, rotating in a first direction followed by its opposite direction limits the amount of winding of components, and can remove the need for rotating couplers. In instances where the treatment vessel is simply rocked back and forth, winding of components can be avoided completely, and rotating couplers can be dispensed with.

Rocking the treatment vessel back and forth, instead of through complete turns, also reduces the risk of the sample falling through the central part of the treatment vessel, which may contain sensitive equipment, such as the electrode, or gas feed.

As noted above, the treatment vessel preferably takes the form of a drum, preferably having a cylindrical outer wall. In such instances, the axis of rotation of the drum preferably extends through the centre of the cylinder. The drum is preferably capped by end-plates, one or both of which may be removable.

Although the methods of agitation are discussed above as an optional addition to the other aspects of the invention set out above, the advantages provided mean that this method of agitation constitutes a separate proposal herein. Accordingly, a separate aspect of the invention provides a method for treating a sample in which the sample is subjected to glow-discharge plasma treatment in a treatment vessel mounted on and rotatable relative to a housing, comprising generating a glow-discharge plasma between opposing electrodes at a region inside the treatment vessel, and rotating the treatment vessel back and forth at an angle greater than 0° but of no more than ±120° no more than ±90°, no more than ±80°, no more than ±70°, no more than ±60°, no more than ±50°, no more than ±45° or no more than ±30° (but preferably at least ±10°, at least ±20°, at least ±30°, or at least ±45°).

Treatment Vessel Construction

To achieve plasma treatment, the sample sits within the treatment vessel above (either directly or indirectly) the counter-electrode, so that plasma is generated in the vicinity of the sample. In such situations, it is only necessary for plasma to form in the region of the treatment vessel in which the sample is held. It is unnecessary for plasma to form in those parts of the treatment vessel where the sample is not present, and indeed, forming plasma in parts where the sample is not present may be undesirable due to the possibility of arcs forming in that region. Thus, the present proposals also include designing the treatment apparatus to minimise or prevent formation of plasma in regions not required for plasma treatment.

In one implementation the interior walls of the treatment vessel have: (i) an electrically conductive surface for supporting the sample during treatment (which serves as the counter electrode), and (ii) one or more electrically insulating surfaces which do not support the sample during treatment. For example, in embodiments where the treatment vessel is a drum (e.g. a cylindrical drum) capped with two end-plates, the internal surface of the drum may be made from an electrically conductive material, and the internal surface of the end-plates may be made from an electrically insulating material. For example, the drum may be made from metal, and the end-plates may be made from glass, ceramic or plastic.

Additionally, or alternatively, the apparatus may have at least one electrode extending within the interior of the treatment vessel and at least one electrode shield extending within the treatment vessel between the electrode and an interior wall of the treatment vessel, wherein the electrode shield is made from an insulating material and is positioned to block (i.e. minimise or prevent) arcing to said interior wall of the treatment vessel in use. The electrode shield may be made entirely from an electrically insulating material, or may have an outer surface made from an electrically insulating material. Materials that may be used in the construction of the electrode shield include, for example, high temperature plastics, PEAK, Teflon, UV-stabilised polycarbonate, ceramics, rubbers and silicon.

In use, the sample will be at the bottom of the treatment vessel due to the action of gravity, and thus it is desirable to focus plasma formation towards the bottom of the treatment vessel. Accordingly, the electrode shield should extend above the electrode and/or to the sides of the electrode. This arrangement has the added advantage of covering the top of the electrode from falling sample, which might otherwise interfere with plasma formation or damage the electrode, a particularly important consideration in the treatment of particulate material.

The electrode shield preferably takes the form of a projection from a wall of the treatment vessel, which extends above the electrode and/or to the sides of the electrode (preferably at least above the electrode). This electrode shield may take the form of a projection curving/bent around the top of the electrode, for example in the form of an upturned U-shaped projection or arcuate projection (e.g. C-shaped or horseshoe shaped). The term “above” and “top” in this context should be interpreted based on a terrestrial reference frame, with gravity pointing downwards.

These electrode shields should be contrasted with the “contact formations” described in WO 2012/076853, because (i) the contact formations are electrically conductive or have an electrically conductive surface, whereas the electrode shield is made from an electrically insulating material; and (ii) the contact formations are intended to contact the sample during treatment whereas the electrode shield should not contact the sample in use. It should be noted that this electrode shield is also different from the “dielectric electrode cover” taught in WO 2012/076853, since the dielectric electrode cover is intended to contact the electrode in use, whereas the electrode shield is spaced apart from the electrode, and does not contact the one or more electrodes or the interior wall of the treatment vessel.

Suitably, the electrode is an elongate electrode extending along a length of the treatment vessel, and the electrode shield extends over at least some (preferably all) of the length of the electrode.

When viewed from above (along the direction of gravity), the electrode shield preferably covers at least 20%, at least 30%, at least 40%, at least 50%, at least 60%, preferably at least 70%, more preferably at least 80%, still more preferably at least 90%, most preferably substantially all of the area of the electrode.

In instances in which the apparatus includes more than one electrode (in addition to the counter electrode), the electrodes may have individual electrode shields, or may have an electrode shield extending over multiple electrodes.

In a particularly advantageous arrangement, the treatment vessel is a cylindrical drum capped with front and back end-plates, wherein the cylindrical drum is made from a conductive material (so as to act as the counter electrode) and the back end-plate has an electrode shield which extends into the interior space of the vessel and overlays the electrode in use. In such an embodiment, the interior surface of the front and back end-plates is preferably made from an insulating material, for example glass or plastic.

In embodiments in which the treatment vessel is rocked (particularly in which the treatment vessel is rocked through a comparatively small angle), the electrode shield may be fixed to the interior wall of the treatment vessel and rock with the treatment vessel without interfering with plasma treatment to any significant degree. However, it is desirable to prevent the electrode shield from rotating along with the treatment vessel, particularly in embodiments in which the treatment vessel is rocked through larger angles or is rotated continuously, to prevent the electrode shield from interfering with plasma formation in the vicinity of the sample.

To avoid rotation of the electrode shield within the treatment vessel, the treatment vessel (e.g. cylindrical drum) may be rotatable about an axial component which extends into the interior of the treatment vessel, with the electrode shield mounted on the axial component. The axial component remains stationary in use, thus allowing the electrode shield to sit in the same place relative to the sample. Preferably, the axial component includes said electrode and said electrode shield. For example, the treatment apparatus may comprise a treatment vessel mounted on, and rotatable about, an axial electrode, wherein the axial electrode is connected to an electrode shield which remains stationary above the axial electrode in use.

Although the electrode shield is discussed above as an optional addition to the other aspects of the invention set out above, the advantages provided mean that this constitutes a separate proposal herein. Thus, in a separate aspect, the present invention provides plasma treatment apparatus, comprising a treatment vessel mounted on and rotatable around an axial component which extends into the interior of the treatment vessel, the axial component comprising at least one electrode and an electrode shield located within the treatment vessel, wherein the electrode shield is located (spaced) between the electrode and the interior wall of the treatment vessel, and wherein the electrode shield is made from an electrically insulating material and the interior of the treatment vessel is made from an electrically conductive material. Preferably, the interior of the treatment vessel serves as the counter-electrode.

Preferably, the treatment vessel comprises a drum (preferably cylindrical drum) capped by a front end-plate and a back end-plate. The drum is preferably made from metal, and the front end-plate and back end-plate are preferably made from an electrically insulating material, such as plastic, glass or ceramic. In a preferred implementation, the plasma treatment apparatus comprises a metal treatment drum mounted on an axial component, the axial component comprising (i) at least one elongate electrode extending along at least part of the length of the treatment drum, and (ii) at least one electrode shield extending over at least some (preferably all) of the length of the electrode.

Another aspect of the present invention provides a method for treating a sample using glow-discharge plasma, in apparatus comprising a treatment vessel mounted on an axial component which extends into the interior of the treatment vessel, the axial component comprising at least one electrode and an electrode shield located within the treatment vessel, the electrode shield being located (spaced) between the electrode and the interior wall of the treatment vessel, the electrode shield being made from an electrically insulating material and the interior of the treatment vessel being made from an electrically conductive material to serve as a counter electrode, the method comprising treating the sample in a glow-discharge plasma formed within the treatment vessel by applying an electric field between the electrode and interior of the treatment vessel whilst agitating the same by rotating the treatment vessel about the axial component.

The skilled reader will know how to distinguish between an electrically conductive and electrically insulating material. The electrically insulating material may have, for example, a resistivity of greater than 10² Ω·m at 20° C., preferably more than 10¹⁰ Ω·m. The electrically conductive material may have a resistivity less than 1 Ω·m.

Pressure Stabilisation Devices/Filter System

In methods of the invention which involve treatment of small discrete parts, it is necessary to design the vessel to retain the sample during treatment. This is particularly important for treatment of particulate material, especially microparticles or nanoparticles. In the present invention, this is preferably achieved by having a solid treatment vessel (i.e. a treatment vessel having impermeable walls) provided with at least one vessel filter.

The vessel filter should be selected as regards its pore size to retain the sample in question, and as regards its material to withstand the processing conditions and to avoid undesirable chemical or physical contamination of the product, depending on the intended use thereof. For the retention of particles, HEPA filters, ceramic, glass or sintered filters may be suitable depending on the size of the particles. The evacuation port may be in a main vessel wall or in a lid or cover.

Generally, during the course of glow-plasma treatment a plasma forming feedstock is continuously fed into the treatment vessel and waste feedstock is exhausted through the vessel filter(s). However, over the course of the plasma treatment the filters can become blocked, due to accumulation of a particulate sample intentionally introduced to the treatment vessel or by detritus formed during treatment. This blockage is a particular concern when the sample is agitated during use, because particulate material can be lifted up or generally ride up the side of the treatment vessel, so as to be at the level of the vessel filter.

Blockage of the vessel filter(s) interferes with removing the waste feedstock from the treatment vessel, and leads to pressure build up. The increase in pressure affects the nature of the plasma formed, and the propensity to form arcs. At a certain point the increase in pressure will prevent the formation of a stable plasma altogether.

If the pressure in the treatment vessel becomes too high, it can be necessary to stop the treatment and manually unblock the filter(s). Consequently, there is a need for methods and apparatus which prevent the vessel filter(s) from becoming blocked over the course of plasma treatment, to allow stable plasma treatment over prolonged periods.

To this end, the treatment vessel of the present invention may have an evacuation port comprising a vessel filter which is protected by a guard element. The guard element blocks particulate material from contacting the vessel filter, whilst still allowing gas to flow to and through the vessel filter.

Within a given treatment step, the glow discharge plasma may be formed in the treatment vessel by supplying a plasma forming feedstock into the treatment vessel, while at the same time removing the waste feedstock through the guard element and then through the vessel filter.

The guard element is not particularly limited and may in principle be any object or barrier which protects the filter.

In one implementation, the guard element is a barrier positioned between the sample and the vessel filter in use, which blocks the movement of sample to the vessel filter. For example, the barrier may be a wall partially or (more preferably) completely surrounding the circumference of the filter. Generally, the treatment vessel is a drum capped by end-plates, with the vessel filter(s) provided on one or both end-plate(s), generally spaced form the edges of the end-plate so as to be placed above the level of the sample in use. The guard element may comprise a wall extending from the end-plate into the interior of the treatment vessel and at least partially surrounding/encircling the filter element. In such instances, the wall serves as a lip which prevents material from lifting up the walls of the treatment vessel into the filter. In such implementations, the guard element may take the form of a tube (having any suitable cross-section, such as cylindrical, or square) extending from the end plate and surrounding (e.g. encircling) the vessel filter. In use, the wall extending from the end-plate does not contact the sample, for example, in embodiments in which the guard element is a tube, the tube does not sweep through the sample. In addition, it is preferred for the wall to extend away from the end-plate for only a relatively short distance, since long walls from the end-plate could interfere with plasma formation. For example, the wall (preferably tube) may extend no more than 30%, nor more than 20%, or no more than 10% into the interior of the treatment vessel (as measured relative to the distance between the interior surfaces of the end-plates of the treatment vessel). In this regard, the guard element should be distinguished from the “contact formations” described in WO 2012/076853 which are specifically positioned to contact and agitate the sample in use.

Alternatively, the guard element may extend (at least in part) from the bottom of the treatment vessel. For example, the guard element may be or comprise a wall extending upwards from the drum's surface to hold back sample from contacting the vessel filter. This wall may take the form of an upstanding wall extending across (e.g. parallel to, but spaced from) the end-plate of the drum. In such instances, the wall acts akin to a dam. Note that this wall is different from the lifter paddles or vanes described in WO 2010/142953 which extend along the axis of rotation to help agitate material, since these lifter formations encourage (instead of prevent) contact of the particulate material with the vessel filter.

Optionally, the guard element comprises a wall extending from the end-plate and a wall extending from the drum which together define a structure which surrounds (e.g. boxes in) the vessel filter. The wall from the end-plate and wall from the drum may be connected to form said structure, or may simply extend into close proximity.

The guard element must allow a gas flowpath from the interior of the treatment vessel to the vessel filter. Optionally, this gas flowpath is itself covered with a guard filter, to limit the possibility of particulate material contacting the vessel filter. For example, the guard element may define an opening (such as a throughhole, gap or slit) which is covered by a guard filter. The opening may have a maximum dimension of, for example, less than 200 mm, or less than 100 mm. In a preferred implementation, the apparatus includes a guard element taking the form of a tube having a first end extending into the interior of the treatment vessel, and a second end extending to the exterior of the treatment vessel, the apparatus further comprising a guard filter disposed towards the first end of the tube, and a vessel filter disposed towards the second end of the tube. In such implementations, the guard filter preferably caps the first end of the tube, to prevent sample from accumulating in the tube in front of the guard filter. Suitably, the guard element is a tube protruding through a hole in the end-plate of the treatment vessel, with the interior end of the tube capped by the guard filter and the exterior end of the tube capped by the vessel filter. Advantageously, in such implementations the guard element may be removably held in the end-plate (ideally from the exterior of the treatment vessel), to facilitate easy removable, replacement and/or cleaning.

The guard filter may be identical to the vessel filter. Alternatively, the guard filter may be coarser than the vessel filter. The guard filter may be, for example, a HEPA, ceramic, glass or sintered filter.

As noted above, the guard element helps to slow or even prevent blockage of the vessel filter, allowing maintenance of stable pressure within the treatment vessel for extended periods of time, and thereby allowing reliable production of plasma with minimisation of arc formation. The increase in pressure within the treatment vessel may be, for example, less than 5% per hour, less than 10% per hour, less than 15% per hour, or less than 20% per hour, as measured for a set rate of gas delivery to the treatment vessel, at a constant temperature (the latter potentially necessitating temperature control taught below, or necessitating measurement at the point at which the temperature has reached a steady equilibrium value during processing). Within a given treatment step preferably, the pressure variation may be less than ±20% of the mean pressure in millibar, preferably less than ±10%, particularly preferably less than ±5%.

The guard element may incorporated in any of the independent proposals/aspects set out above.

Although the guard element is discussed above as an optional addition to the other proposals/aspects of the invention set out above, the advantages provided mean that this constitutes a separate proposal herein. Thus, in a separate aspect, the present invention provides plasma treatment apparatus for treating a particulate material, comprising a treatment vessel suitable for receiving a particulate material, mounted on/in and rotatable relative to a housing, the treatment vessel having an evacuation port comprising a vessel filter which is protected by a guard element, the guard element blocking particulate material from contacting the vessel filter in use. In a preferred embodiment, the treatment vessel is mounted within, and rotatable relative to, a housing. In such instances, the treatment vessel may take the form of a drum capped by two end-plates, wherein the vessel is rotatable relative to the housing about an axis passing through the two end plates. Optionally, the guard element comprises a wall extending from one of the end-plates, as set out above. Optionally, the guard element comprises a wall extending upwards from the drum's interior surface. Optionally the guard element comprises a wall extending from one of the end-plates and a wall extending upwards from the drum's interior surface, which together define a structure which surrounds (e.g. boxes in) the vessel filter. The apparatus may have any of the optional or preferred features set out above. A further independent proposal/aspect of the present invention provides a method for treating a particulate sample (for example, microparticles, nanoparticles etc.) using such apparatus, involving forming a glow discharge plasma within the treatment vessel and agitating the particulate sample within the treatment vessel (preferably by rotating/rocking the treatment vessel relative to the housing), in which the guard element limits or prevents the particulate sample from contacting the vessel filter.

The methods and apparatus described above help to improve pressure control during the plasma treatment and can also help to improve the shelf life of the filters.

Heated/Cooled Reaction Chamber

During the course of treatment the apparatus and sample may heat up. This heating may be caused by resistive heating of the electrical components of the apparatus, in particular, heat generated by the electrode. In instances where the sample is agitated during use, heating may also arise through friction. Such heating may lead to degradation of the material being treated (for example, stripping away surface functionalisation) and may damage the plasma treatment apparatus. For example plastic materials may degrade/melt at temperatures of about 100° C. and graphene is damaged at temperatures above 400° C.

In other instances, heating of the treatment apparatus can be advantageous. For example, it can limit or prevent condensation of unwanted liquids within the treatment vessel, and can also help to drive desired treatment steps, such as functionalisation.

Accordingly, in the present invention, the treatment vessel is optionally provided with a temperature control system, for cooling and/or heating the treatment vessel in use.

Suitably, the temperature control system is for cooling and/or heating the walls of the treatment vessel—that is, the surface which contacts the sample in use. To achieve this the temperature control system may be mounted on or in the exterior walls of the treatment vessel.

The temperature control system may be an electronic heating/cooling system, such as a system based on resistive heating or thermoelectric (Peltier) heating. Additionally or alternatively, the temperature control system may be a fluid-based heating/cooling system, preferably a liquid-based heat transfer system, such as a water- or oil-based heat transfer system. When an oil-based heat transfer system is used the temperature of the treatment vessel may be determined by measuring the inlet temperature of the oil and using a formula to determine the temperature of the treatment vessel based on the inlet temperature of the oil.

Within a given treatment step the temperature controlled treatment vessel may be held at a constant temperature such as e.g. from about −20° C. to about 120° C., or from about 10° C. to about 80° C., or from about 20° C. to about 50° C. or about room temperature (25° C.). The temperature used may be tailored to the treatment gas being used for glow plasma formation, for example treatment with oxygen (O₂) gas may be carried out a low temperatures of from about −20° C. to about 0° C.; whereas treatment with ammonia (NH₃) may be carried out at higher temperatures such as from about 60° C. to about 120° C.

When the temperature is controlled by a fluid-based heating/cooling system, the temperatures discussed above correspond to the temperature of the heating/cooling fluid immediately before entering the treatment vessel. More generally, the temperature may be determined based on the pressure change within the treatment vessel, or based on the difference between the flow rate ratios of feedstock entering the treatment vessel and feedstock leaving the treatment vessel required to maintain constant pressure within the treatment vessel.

In instances where the treatment vessel is rotated (continuously or partially) the design of the temperature control system is not straightforward. In particular, positioning the temperature control system internally within the treatment vessel can lead to interference between this system and the sample (and vice versa), as well as interference with plasma formation. Positioning the temperature control system outside the treatment vessel avoids interfering with the sample and plasma, but can instead interfere with the mechanics required to rotate the vessel. For example, mounting the temperature control system at only a single location can lead to the vessel becoming unbalanced during rotation, putting strain on the plasma apparatus during rotation. Furthermore, the vessel is generally mounted within a fixed housing via rollers, which support the vessel in use, and the provision of temperature control components on the outside of the treatment vessel may prevent the vessel from rotating over the rollers, or cause bumping of the vessel over the rollers.

With this in mind, the inventors have developed temperature controlled systems specifically suited to the treatment of samples in a rotating vessel.

In particular, in instances where the method involves rotating (continuously or partially) the treatment vessel around an axis which extends through a back end and a front end of the treatment vessel, the temperature control system preferably comprises at least one vessel heat-transfer line mounted on or in the exterior wall of the treatment vessel, and a heat-transfer input line connected to the at least one vessel heat-transfer line at said back end or front end of the treatment vessel. (For the avoidance of doubt, the word “line” is intended to cover both fluid and electrical systems, for example, to refer to both tubing and/or an electrical wire). The heat-transfer input line is connected to a heat supply (such as an oil or water heater, or a source of electricity in the case of an electric heating system). Preferably, the connection between the at least one vessel heat-transfer line and the heat-transfer input line occurs at (or close to) the axis of rotation of the treatment vessel, so as to prevent the point of connection moving in an arc or a circle as the treatment vessel rotates.

According to this implementation, the vessel heat-transfer lines can be designed and configured so as to permit efficient rotation of the barrel. Furthermore, positioning the input line at the back end or front end, instead of around the rotating circumference of the treatment vessel, means that the heat-transfer feed can be positioned away from any rollers which support the treatment vessel, and in such a way as to prevent the system from becoming unbalanced.

Optionally, the at least one vessel heat-transfer line is connected to the heat-transfer feed line through a rotating coupler, which allows the vessel heat-transfer line and heat-transfer feed to rotate relative to one another. This limits or prevents winding of the feed line and vessel heat-transfer line. Preferably, the at least one vessel heat-transfer line is connected to the heat-transfer feed line through a rotating coupler aligned with the axis of rotation of the treatment vessel, since this configuration can completely eliminate any winding of the vessel heat-transfer line(s) and heat-transfer feed line.

In some implementations, it may be possible to effectively heat the treatment vessel solely through the heat-transfer input line. For example, a heating/cooling fluid may undergo repeated cycles of being flowed into the at least one vessel heat-transfer line, and then removed from the at least one vessel heat-transfer line through the heat-transfer input line.

However, in other implementations it is advantageous to connect the at least one vessel heat-transfer line to both a heat-transfer input line and a heat-transfer output line, to permit the continuous flow of heating/cooling fluid or electricity.

In one implementation, the connection between the vessel heat-transfer line and heat-transfer input line occurs at one end of the treatment vessel, and the connection between the vessel heat-transfer line and heat-transfer output line occurs at the other end of the treatment vessel. In such instances, the vessel heat-transfer line may extend from one end of the treatment vessel to the other end, for example, in a straight line or by coiling around the treatment vessel, e.g. in the form of a helix.

In these embodiments, it is advantageous for the connection between the at least one vessel heat-transfer line and the heat-transfer input line to occur at (or close to) the axis of rotation on one side of the treatment vessel, and the connection between the at least one vessel heat-transfer line and the heat-transfer out line to occur at (or close to) the axis of rotation at the other side of the treatment vessel. As set out above, this arrangement minimises movement of the connections in an arc or a circle as the treatment vessel rotates. When rotating couplers are used for each connection in this arrangement, winding of the temperature control system components can be avoided altogether.

Preferably, connections to the heat-transfer input line and heat-transfer output line occur at the same end of the vessel. This may be achieved, for example, by providing the at least one vessel heat-transfer line with one or more bends. For example, the at least one vessel heat-transfer line may pass back and forth from one end of the vessel to the other in the form of a zigzag, or with U-shaped bends, with points for connecting to the heat-transfer input line and heat-transfer output line provided at the same end of the treatment vessel.

In these embodiments, it is again advantageous for the connection between the at least one vessel heat-transfer line and both the heat-transfer input line and heat-transfer output line to occur at (or close to) the axis of rotation, so to minimise movement of the connections in an arc or a circle as the treatment vessel rotates. This may be achieved, for example, by having the connection points at different points along the axis of rotation, i.e. with one connection point positioned relatively further forward than the other connection point. Again, when rotating couplers are used for each connection in this arrangement, winding of the temperature control system components can be avoided altogether.

Suitably, the treatment vessel takes the form of a drum having a side-wall and front and back walls, with the drum rotating about an axis passing through the front and back walls. In such instances, the at least one vessel heat-transfer line extends around the side-wall of the drum, and the heat-transfer input line is preferably coupled to the vessel heat-transfer line(s) through a connection at the front or back wall.

As noted above, in many instances it is useful to use rotating couplers to connect the vessel heat-transfer line(s) to the heat-transfer input line. However, in instances where the treatment vessel is rocked back and forth, the temperature control system is not subject to continued winding, and thus the rotatable coupler can be dispensed with. Thus, in an advantageous embodiment, the methods of treating a sample discussed above involve agitating the sample by rocking the treatment vessel back and forth, wherein the treatment vessel is provided with a temperature control system. In such instances, the temperature control system may again include at least one vessel heat-transfer line provided in or on the treatment vessel without the use of a rotating coupler, since the amount of twisting and/or winding between the heatable elements and the stationary heat supply element is limited. In this implementation, the vessel heat-transfer line and heat-transfer input line can be separate parts connected through a (non-rotatable) coupler, or can be integral to one another (for example, a continuous tube or wiring). This is particularly advantageous from an economic perspective, as rotatable couplers can make the temperature control system more expensive and more complicated. Additionally, from a safety perspective, if an oil heater line is being used to control the temperature of the treatment vessel, it is advantageous to avoid using a rotatable coupler. This is because using a rotatable coupler carries the risk of hot oil spilling out of the coupler if the seal is not completely tight. Loosening of a rotatable coupler may occur during normal operation of a rotatable coupler.

Although the temperature control system is discussed above as an optional addition to the other aspects of the invention set out above, the advantages provided mean that this constitutes a separate proposal herein. Thus, a further aspect provides a method for treating a sample using glow-discharge plasma, in which the sample for treatment is subject to plasma treatment in a treatment vessel provided with a temperature control system, wherein the treatment vessel is rotated about an axis during use in order to agitate the sample, and wherein the temperature control system is used to cool or heat the sample. Optionally, the rotation is continuous rotation, and the temperature control system comprises one or more heatable elements provided in or on the treatment vessel (for example, cooling/heating fluid supply lines electrical wiring such as trace heaters) coupled to a heat supply element via a rotatable coupler. Optionally, the rotation is back and forth (preferably less than a full turn in each direction, as set out above). The treatment vessel is preferably a drum (e.g. cylindrical drum) capped by end-plates, wherein the drum is rotated about a central axis running through the end-plates.

A further aspect also provides apparatus for treating a sample according to the method outlined above. This apparatus comprises a treatment vessel provided with a temperature control system, and an electrode, counter-electrode and power supply for forming a glow discharge plasma in the treatment vessel in use, wherein the treatment vessel is mounted within a housing and rotatable relative to the housing to agitate the sample in use.

Optionally, the treatment vessel is a cylindrical drum supported within said housing by rollers, the drum being rotatable around the axis of the cylinder upon said rollers, the at least one heat-transfer line being located within the exterior walls of the drum, and the connection between the at least one heat-transfer line and heat-transfer input line being positioned at said axis of rotation, optionally wherein said connection is through a rotating coupler.

Treatment Types

The one or more treatment steps discussed above may have the effect of disaggregating, deagglomerating, exfoliating, cleaning, functionalising, or quenching the sample, or some combination of these effects.

The effect of the first treatment step may be different to that of subsequent treatment steps. For example, the first treatment step may be a cleaning step, and the second treatment step may be a disaggregating/functionalising step.

In functionalisation steps, the treated materials may be chemically functionalised by components of the plasma-forming feedstock, forming e.g. carboxy, carbonyl, OH, amine, amide, imine or halogen functionalities on their surfaces. The chemical functionalities may also be found inside the materials itself, as a result of the plasma forming feedstock permeating into the material being functionalised. Functionalisation using methods of the present invention generally results in permanent or long term functionalisation of the materials being treated, with the functionalities covalently bonded to the materials that have been treated.

Without wishing to be bound by any theory, it is believed that the methods described above allow accurate control of the levels of plasma treatment and functionalisation, particularly when all of the various elements described above are used together. These processes allow materials with both hydrophobic and hydrophilic or other desirable solvent or matrix interaction properties to be realised. The treated materials may be functionalised by forming carboxylic, amine and other oxidative modifications on the particle surfaces. Alternatively, the materials may undergo fluorination, or silanation. Additionally, it is possible to achieve bespoke functionalisation with the chemical groups selected from carboxylic, carbonyl, hydroxyl and epoxide. Furthermore, it is possible to teflonise materials using the methods described above, meaning that a number of the C—H bonds in the material have been fluorinated.

The method may involve applying a quenching step after a functionalisation step. By “quenching” we mean applying a treatment to deactivate certain reactive groups remaining after functionalisation. This may help prevent the groups on the surface of the material from being degraded when exposed to oxygen in the air. For example, the quenching step may involve performing a treatment step using hydrogen gas as the feedstock.

Plasma treatment of the present invention can allow 3 dimensional treatment directed only at exposed surfaces, thus maintaining the structural integrity of the materials being treated. Alternatively, the present inventors have found that the proposals set out above allow treatment to penetrate beyond the initial surface layer deeper into the material, without destroying the initial surface layer. This is particularly true for the higher power treatment levels which are accessible through the combined use of the different transformer settings and modulated power delivery, which can achieve more penetrating treatment (e.g. functionalisation) than those achieved in the earlier applications WO 2010/142953 and WO 2012/076853.

Cleaning steps may be carried out before all other treatment steps, between other treatment steps and/or after all other treatment steps. For example, the first treatment step may be a cleaning step. Alternatively, the first treatment step may be a disaggregating/functionalising step, and the second treatment step may be a final cleaning step. Cleaning steps can be carried out with an inert gas such as argon.

A typical plasma treatment process may have up to 10 treatment steps.

Plasma-Forming Feedstock

The plasma-forming feedstock is a fluid, and may be a gas, vapour or liquid. The feedstock may be a mixture of different fluids. The feedstock may be, for example, any of oxygen, water, hydrogen peroxide, alcohol, nitrogen, ammonia, amino-bearing organic compound, halogen such as fluorine, halohydrocarbon such as CF₄ and noble gas.

Preferably, the first treatment step involves forming a glow-discharge plasma with a first plasma-forming feedstock, the second (or subsequent) treatment step involves forming a glow-discharge plasma with a second, different, plasma-forming feedstock. Advantageously, in such an instance the first transformer setting is chosen to achieve efficient plasma formation using the first plasma-forming feedstock, and the second (and subsequent) transformer setting is chosen to achieve efficient plasma formation using the second plasma-forming feedstock.

For example, one possibility is to carry out a first plasma treatment with a first feedstock to clean the sample surface, and a second plasma treatment with a second feedstock to functionalize the surface.

Alternatively, one could treat with a feedstock to introduce chemical groups at the sample surface, and a second feedstock to alter those chemical groups, to efficiently provide functionalisation not accessible using a single treatment feedstock. Examples of multiple functionalisation treatments include:

The first treatment step involving formation of a glow-discharge plasma using carbon tetrafluoride (CF₄) as a plasma-forming feedstock, and the second treatment step involving formation of a glow-discharge plasma using ammonia (NH₃). Fluorinating before treating with NH₃ increases the NH₃ functionalisation by providing access sites for substitution-in of amine groups.

The first treatment step involving formation of a glow-discharge plasma using fluorine, and the second treatment step involving formation of a glow-discharge plasma using oxygen. In this method, fluorine can readily be displaced by carboxylic acid groups.

The first treatment step involving formation of a glow-discharge plasma using oxygen, and the second treatment step involving formation of a glow-discharge plasma using an amine, such as ammonia, ethanolamine, or ethylene diamine.

Functionalisation steps may be preceded and/or proceeded by cleaning steps.

The feedstock may also be in the form of a liquid or vapour, such as e.g. water, hydrogen peroxide or alcohols.

The liquids and/or vapours may be supplied into the treatment vessel by bubbling a carrier gas through a bubbler filled with the liquid of interest either as the pure substance or as part of a mixture, for example hydrogen peroxide may be supplied by bubbling a carrier gas through a solution of hydrogen peroxide in water.

Alternatively, the system for supplying liquids and/or vapours may be a mechanical or motorised injection system. For example, the liquid and/or vapour may be directly injected into the treatment vessel, optionally with concomitant supply of a plasma-forming gas to the treatment vessel.

Preferably, feedstock supply lines include line heaters. This can be achieved efficiently though the use of trace heaters. This is particularly useful when suppling a vapour to the treatment vessel, as in some cases it is necessary to maintain the vapour at a particular temperature to prevent it from condensing back into liquid form in the supply lines.

Gases (or vapours) may be fed into the treatment vessel at a number of different locations. They may be provided through one or more vents or holes along the length of the one or more electrodes, alternatively or additionally the treatment gas may be provided through a vent at the end of the one or more electrodes, and/or through one or more vents in a wall of the treatment vessel.

The apparatus may also comprise a mass flow controller for mixing gases. This means that two or more gases can be mixed together efficiently. A mixture of gases can then be fed into the treatment vessel in one or more of the treatment steps. Additionally, the apparatus may comprise an automatic safety purge system, this allows the gas lines to be purged of gas prior to the beginning of the treatment step.

Different gases, liquids and/or vapours may be fed into the treatment vessel in different treatment steps. In this case, preferably the gas lines are automatically purged between each step.

Plasma Formation

The plasma treatment is by means of low-pressure plasma of the “glow discharge” type.

The pressure in the treatment vessel is desirably less than 1000 Pa, more preferably less than 500 Pa, less than 300 Pa and most preferably less than 200 Pa or less than 100 Pa.

For the treatment of CNTs and graphitic particles especially, pressures in the range 0.05-5 mbar (5-500 Pa) are usually suitable, more preferably 0.1-2 mbar (10-200 Pa).

To generate low-pressure or glow plasma, the treatment vessel needs to be evacuated. An evacuation port may be provided for this purpose, and in the present method is connected to an evacuation means via a suitable vessel filter for retaining the materials, as discussed above.

### PREFERRED EMBODIMENTS

Particularly preferred embodiments include:

A method for treating a sample using glow-discharge plasma, in an apparatus comprising a treatment vessel, an electrode, a counter-electrode, and a power supply comprising one or more transformers and having a first transformer setting and a second transformer setting, the method comprising:
a loading step, involving loading the sample into the treatment vessel;
a first treatment step involving treating the sample in a glow-discharge plasma formed within the treatment vessel by applying an electric field between the electrode and counter-electrode at the first transformer setting;
a second treatment step involving treating the sample in a glow-discharge plasma formed within the treatment vessel by applying an electric field between the electrode and counter-electrode at the second transformer setting; and
a removal step, involving removing treated sample from the treatment vessel,

wherein the power supplied from the power supply during the first and/or second treatment step is modulated periodically between a higher power level and a lower (preferably no) power level. Preferably, the power is modulated during a treatment step between >0 W (the higher power level) and 0 W (lower power level) at a frequency of from 500 Hz to 1000 Hz, optionally with the ratio of time spent at the higher power level compared to the lower power level being at least 1.

Preferably, the first transformer setting has a different voltage ratio to the second transformer setting.

Preferably, the first transformer setting has a different secondary voltage rating to the second transformer setting.

Preferably, the first and second treatment steps are sample functionalisation steps.

In these preferred embodiments, the treatment vessel is preferably rocked back and forth about an axis to cause agitation of the particulate material, with gas removed from the interior of the treatment vessel via an evacuation port, and the evacuation port includes a vessel filter which is protected by a guard element, the guard element blocking particulate material from contacting the vessel filter.

In these preferred embodiments, the treatment vessel may be a temperature controlled treatment vessel, with the temperature held at a constant temperature of from about −20° C. to about 120° C. during the first and/or second treatment step.

Preferably, the said electrode extends within the interior of the treatment vessel and at least one electrode shield extends within the treatment vessel between the electrode and an interior wall of the treatment vessel, wherein the electrode shield is made from an insulating material and is positioned to block arcing to said interior wall of the treatment vessel when in use.

In a further particularly preferred embodiment the present invention relates to a method for treating a sample using glow-discharge plasma, in an apparatus comprising a treatment vessel, an electrode, a counter-electrode, and a power supply comprising one or more transformers and having a first transformer setting and a second transformer setting, the method comprising:
a loading step, involving loading the sample into the treatment vessel;
a first treatment step involving treating the sample in a glow-discharge plasma formed within the treatment vessel by applying an electric field between the electrode and counter-electrode at the first transformer setting;
a second treatment step involving treating the sample in a glow-discharge plasma formed within the treatment vessel by applying an electric field between the electrode and counter-electrode at the second transformer setting; and
a removal step, involving removing treated sample from the treatment vessel,

wherein the treatment vessel is a temperature controlled treatment vessel and the said electrode extends within the interior of the treatment vessel and at least one electrode shield extends within the treatment vessel between the electrode and an interior wall of the treatment vessel,

wherein the electrode shield is made from an insulating material and is positioned to block arcing to said interior wall of the treatment vessel when in use,

wherein during the first and/or second treatment step the power supplied from the power supply is modulated periodically between a higher power level and a lower (preferably no) power level, the temperature is held at a constant temperature of from about −20° C. to about 120° C. and the treatment vessel is rocked back and forth about an axis to cause agitation of the particulate material, with gas removed from the interior of the treatment vessel via an evacuation port, and the evacuation port includes a vessel filter which is protected by a guard element, the guard element blocking particulate material from contacting the vessel filter.

### BRIEF DESCRIPTION OF THE FIGURES

The present proposals are now explained further with reference to the accompanying figures in which:

FIG. 1 is a side cross-sectional view of a plasma treatment apparatus used in examples 1 to 3;

FIG. 2 is a side cross-sectional view of plasma treatment apparatus incorporating an electrode shield according to the present invention;

FIG. 3 is a front cross sectional view of the plasma treatment apparatus in FIG. 2;

FIG. 4 is a diagram of an electrode shroud used to mount the electrode shield in FIG. 2;

FIG. 5A is a partial side cross-sectional view of plasma treatment apparatus showing guard elements according to a first embodiment;

FIG. 5B is a partial side cross-sectional view of plasma treatment apparatus showing guard elements according to a second embodiment;

FIG. 6 is a diagram of the fluid delivery system for the plasma treatment apparatus;

FIG. 7 is a plot showing the stability of dispersions of graphene nanoplatelets subjected to oxygen plasma treatment using different transformer settings;

FIG. 8 is a section of the plot shown in FIG. 7;

FIG. 9 is a plot showing the stability of dispersions of GNP-type materials subjected to oxygen plasma treatment;

FIG. 10 is a plot showing the stability of dispersions of FLG-type materials subjected to oxygen plasma treatment;

FIG. 11 is a plot showing the number of arcs detected for a number of different carbon materials using plasma treatment apparatus with and without end plates;

FIG. 12 is a plot showing the pressure and voltage over time for a plasma treatment apparatus without endplates;

FIG. 13 is a plot showing the pressure and voltage over time for a plasma treatment apparatus with endplates;

FIG. 14 is a plot showing the number of arcs detected before and after the use of a pulsing generator with the plasma treatment apparatus.

FIG. 15 is a plot showing the atomic percentage of oxygen, carbon, nitrogen, fluorine, boron and silicon in a sample of boron nitride after plasma treatment with a plasma formed from argon, acrylic, ammonia, oxygen or tetrafluoromethane (CEO.

FIG. 16 is a plot showing the effect of heating the reaction chamber on the degree of functionalisation of FLG-type materials.

### DETAILED DESCRIPTION

Unless defined otherwise, all technical and scientific terms used herein have the same meaning as commonly understood by one of ordinary skill in the art to which the invention pertains. Although, any methods and materials similar or equivalent to those described herein can be used in practice for testing of the present invention, the preferred materials and methods are described herein. In describing and claiming the present invention, the following terminology will be used in accordance with the definitions set out below. Unless clearly indicated otherwise, use of the terms “a,” “an,” and the like refers to one or more.

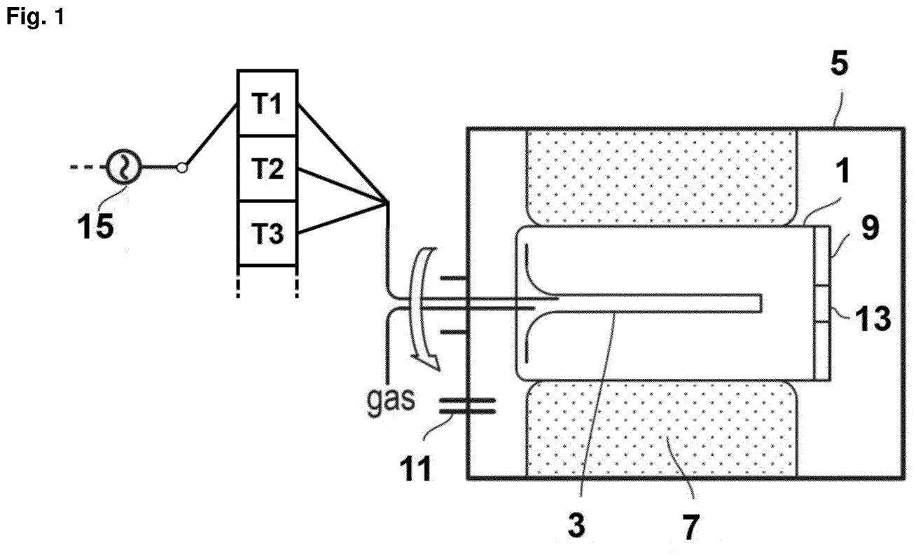

The apparatus shown in FIG. 1 consists of a treatment vessel 1, having a central axial electrode 3 extending therein, loaded into a support container 5 and held in position by locating pads 7. The support container is rotatably mounted in a fixed sealable housing (not shown), so as to allow rotation of the treatment vessel during use. The central axial electrode 3 incorporates multiple gas feed channels, for feeding gas to the vessel interior via a filter at the front end of the electrode.

To use the equipment, a sample is loaded into the treatment vessel 1 via the removable lid 9, and the pressure in the treatment vessel is reduced by applying a vacuum to an evacuation port on the vessel housing, with the vacuum extending to the treatment vessel through vacuum port 11 and front filter port 13 of the treatment vessel. Next a plasma-forming gas is supplied to the treatment vessel interior via the gas feed channel in electrode 3, and a plasma formed through application of power to the central axial electrode 3. During processing, the treatment vessel 1 is rotated relative to the sealable housing, such that the sample held in the treatment vessel is tumbled through the plasma during processing.

The power supply includes a power source 15 capable of supplying AC power to the electrode via an array of step-up transformers, T₁, T₂, T₃, having different secondary voltage ratings. The power source is designed to supply up to 400 V at a frequency of between 25 and 35 kHz. In the experiments described below, the apparatus is switched between seven different transformers, having secondary voltage ratings of 0.5, 1.0, 1.5, 2.0, 2.5, 3.0 and 3.5 kV respectively.

The apparatus includes an arc detection unit, which monitors the power supply to look for changes in the power, voltage, and frequency required to maintain the desired settings which are indicative of arc formation. Upon detection of an abnormality in the power supply, the system is configured to temporarily shut down for several seconds before restarting.

The power source 15 outputs a modulated power supply, switching between higher and lower power levels during the course of a treatment step. In this particular embodiment, the modulation occurs according to a sine wave.

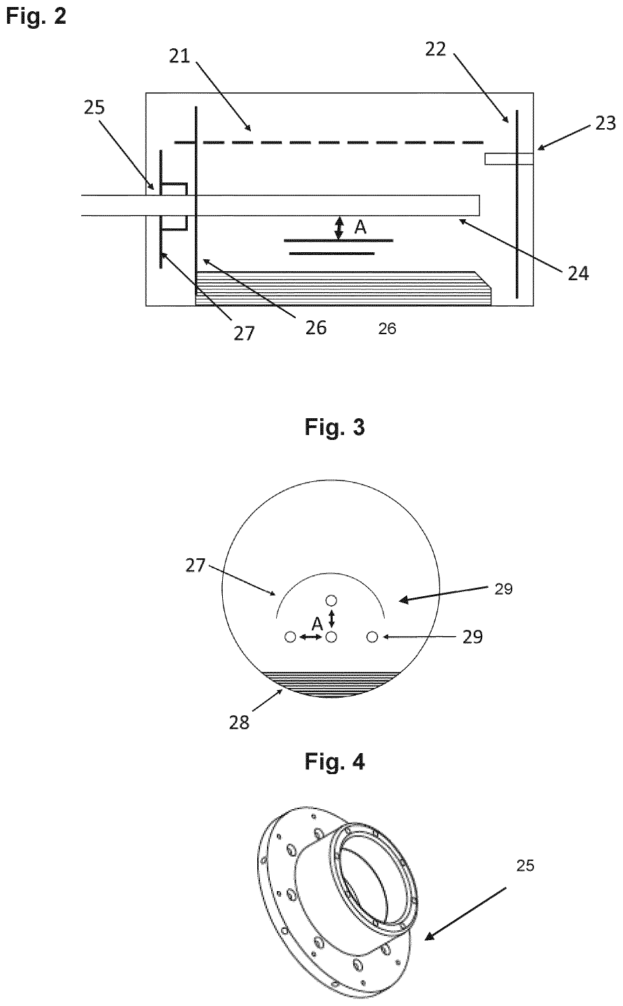

FIGS. 2-4 show a modified plasma treatment apparatus, the features of which can be incorporated into the apparatus of FIG. 1. The apparatus consists of a treatment vessel rotatable about a fixed axial electrode 24 extending into the treatment vessel through seal 25. The axial electrode 24 is fixed to an electrode collar 27 (shown in more detail in FIG. 4), which support a number of subsidiary electrodes 29 between the axial electrode and particulate sample 28, separated from the axial electrode 24 by a distance “A”. Electrode shield 21 is also mounted to electrode collar 27, and covers the electrode assembly. The electrode shield 21 is formed from an electrically insulating material, so as to focus plasma formation in the lower half of the treatment vessel, and interrupt formation of arcs to the drum of the treatment vessel (which serves as the counter-electrode in this case). The front of the treatment vessel takes the form of a removable lid 22. The lid is made from an insulating material to prevent the formation of arcs. Gas feed 23 is provided to supply plasma-forming feedstock to the treatment vessel.

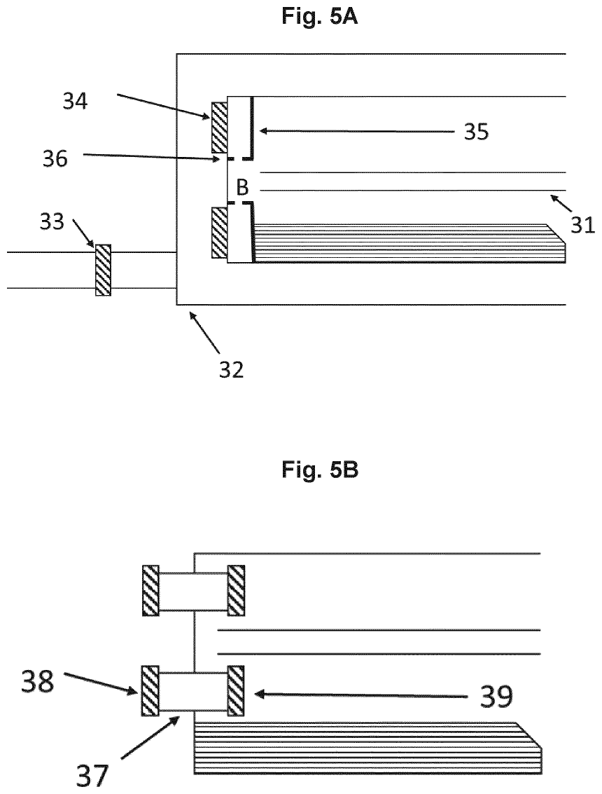

FIGS. 5A and 5B show the front end of a treatment vessel according to the invention comprising a vessel filter and guard element as described above.

In the embodiment shown in FIG. 5A, the treatment vessel is loaded in and rotatable relative to housing 32. Gas is supplied to the treatment vessel through electrode 31. Gas is removed from the system by a vacuum applied to the housing, operating via housing filter 33, which reduces pressure in the treatment vessel via vessel filters 34. The vessel filter is separated from the material being treated by a guard element, formed from upright wall 35 extending from the drum's interior surface, and a top wall 36 extending from the end-plate of the drum. The top wall 36 is provided with a bleed-through hole “B” to allow air to exit the treatment vessel through the filters.

In the embodiment of the treatment vessel shown in FIG. 5B, the guard element instead takes the form of a tube 37 extending through the front end-plate of the drum, capped by a guard filter 39 and a vessel filter 38. The tube is positioned above the level of the particulate sample, and thus prevents ingress of the sample through the guard filter.

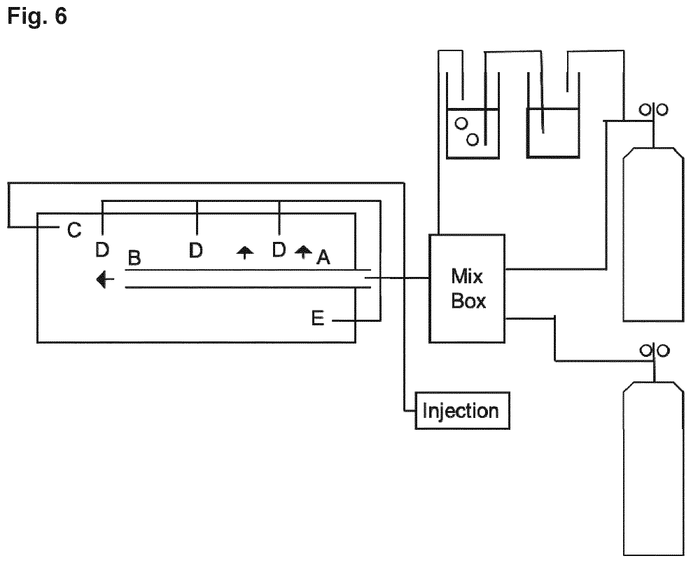

FIG. 6 is a diagram of the how gas, liquids or vapours may be delivered to a treatment vessel. Gases, liquids or vapours may be delivered through vents along the length of a central electrode A, through a vent at the end of a central electrode B, through vents in the front wall of the treatment vessel C, through vents in the side walls of the treatment vessel D or through vents in the rear wall of the treatment vessel. An injection unit allows liquid or vapour to be delivered into the treatment vessel. A mix box comprising a mass flow controller allows two or more different gases to be fed into the treatment vessel. The gas lines may also comprise trace heaters, which allow the gas lines to be held at a particular temperature.

### EXAMPLES

### Examples 1 to 3

Examples 1 to 3 were conducted to demonstrate the effect of the transformer setting on the performance of apparatus as described in FIG. 1 above.

### Example 1

A series of experiments were conducted to show the effect of selecting different transformers on the power supplied to the electrode during plasma formation.

An air plasma was formed at a pressure of 70 Pa with 100 W of power supplied via a 0.5 kV transformer. The experiments were then repeated with different transformers in place of the 0.5 kV transformer. The treatment vessel did not include any particles.

For each transformer, the voltage and frequency required to maintain the 100 W power level was recorded. The voltage was then converted to a voltage rating percentage (“% V”) value by expressing the voltage generated by the transformer (as measured at the electrode) as a percentage of the transformer secondary voltage rating of the transformer.

TABLE 1

| Transformer | Run 1 | | Run 2 | | Run 3 | | Average | |
|---|---|---|---|---|---|---|---|---|
| (kV) | % V | kHz | % V | kHz | % V | kHz | % V | kHz |
| 0.5 | 86.8 | 35.5 | 87.2 | 37 | 86.2 | 36 | 86.7 | 36.2 |
| 1 | 45.9 | 36 | 46.2 | 36.7 | 44.8 | 35.8 | 45.6 | 36.2 |
| 1.5 | 31.2 | 33.6 | 31.2 | 34 | 30.3 | 33 | 30.9 | 33.5 |
| 2 | 23.8 | 27.6 | 23.7 | 28.4 | 23.4 | 28 | 23.6 | 28 |
| 2.5 | 19.9 | 22.2 | 19.4 | 22.5 | 19.4 | 22.7 | 19.6 | 22.5 |
| 3 | 17.3 | 18.1 | 16.8 | 18.2 | 16.9 | 18.6 | 17 | 18.3 |
| 3.5 | 15.4 | 15.2 | 15.2 | 15 | 15.2 | 15.4 | 15.3 | 15.2 |

These results show that the power source had difficulty in maintaining the required power level as the rating of the transformer increased. For example, when power was supplied via the 0.5 kV transformer, the source was able to supply power at its rated frequency (25-35 kHz) and the transformer operated at ˜86.7% of the voltage rating. In contrast, when power was supplied via the 3.5 kV transformer the system operated inefficiently, with greater output from the source required to maintain the required power level at the electrode. The greater demands placed on the power source led to a drop in frequency below the rating of 25-35 kHz.

### Example 2

A series of experiments were conducted to show the effect of selecting different transformers on the number of arcing events detected by the plasma apparatus.

Graphene nanoplatelets (260 g) were loaded into the treatment vessel, and subjected to functionalisation with an oxygen plasma treatment at 70 Pa with 100 W of power supplied via a 0.5 kV transformer. The experiments were then repeated with different transformers in place of the 0.5 kV transformer.

For each transformer, the voltage rating percentage and frequency required to maintain the 100 W power level was recorded, along with the number of arcs detected by the arc detection unit. The detected arcs were observed to be “phantom” arcs, caused through changes in the power supply. In each case, detection of the arc led to shutdown of the apparatus for several seconds before restarting.

TABLE 2

| | Run 1 | | Run 2 | | Number of |
|---|---|---|---|---|---|
| Transformer (kV) | % V | kHz | % V | kHz | arcs detected |
| 0.5 | 99.9 | 37.3 | 93.7 | 36.9 | 5 |
| 1 | 48.1 | 37 | 47.2 | 37.2 | 32 |
| 1.5 | 34.2 | 36.1 | 32.9 | 35.9 | 75 |
| 2 | 25.1 | 33.3 | 24.8 | 33 | 75 |
| 2.5 | 20.8 | 29.9 | 20.3 | 29.4 | 39 |
| 3 | 17.8 | 25.7 | 17.3 | 25 | 33 |
| 3.5 | 15.6 | 22 | 15.3 | 21.3 | 33 |

These results show that the power source had difficulty in maintaining the required power level as the rating of the transformer increased, in a similar manner to that observed in Example 1. In addition, the data show that the number of phantom arcs detected increased markedly from the 0.5 kV transformer to the 1.5 kV transformer, and then decreased again at transformer rating above 2.5 kV. These “phantom” arcs are indicative of electrical fluctuations in the power source caused by incompatibility of the transformer setting with the particular conditions chosen.

### Example 3

A series of experiments were conducted to show the effect of selecting different transformers on the degree of graphene nanoplatelet functionalisation.

Graphene nanoplatelets were subjected to oxygen-plasma functionalisation following the procedure described in Example 2, but using a different power setting. The resulting graphene nanoplatelets were then dispersed in water, and the degree of functionalisation due to oxygen-plasma treatment was assessed by monitoring light transmittance through the dispersion over time, following the methods described in the examples of WO 2015/150830. The stability of a dispersion of untreated graphene nanoplatelets was also assessed, to serve as a control experiment. In all cases, the slower the decrease in light transmittance, the more stable the dispersion.

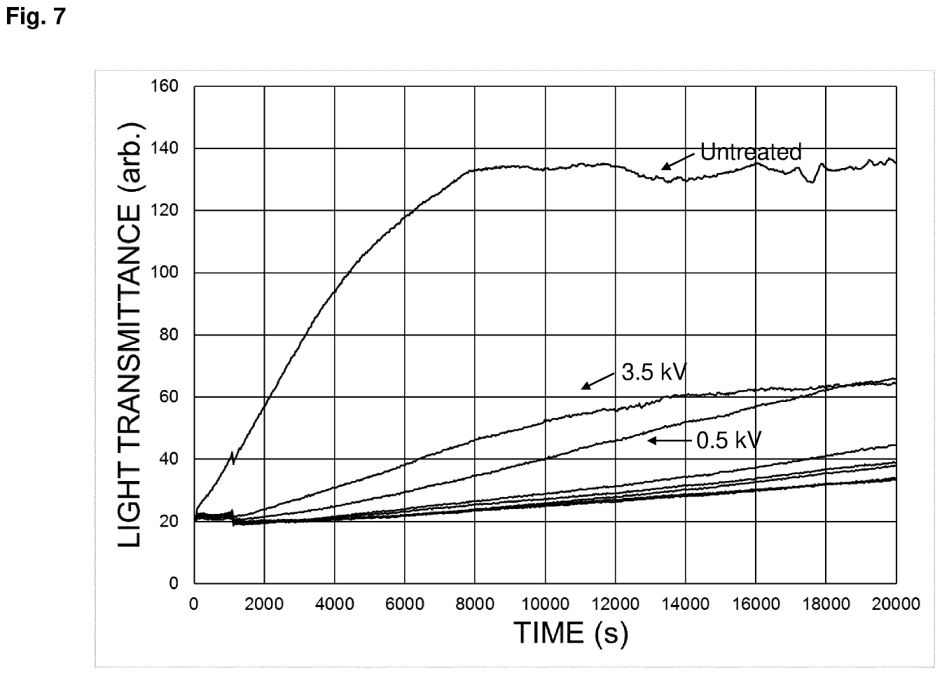

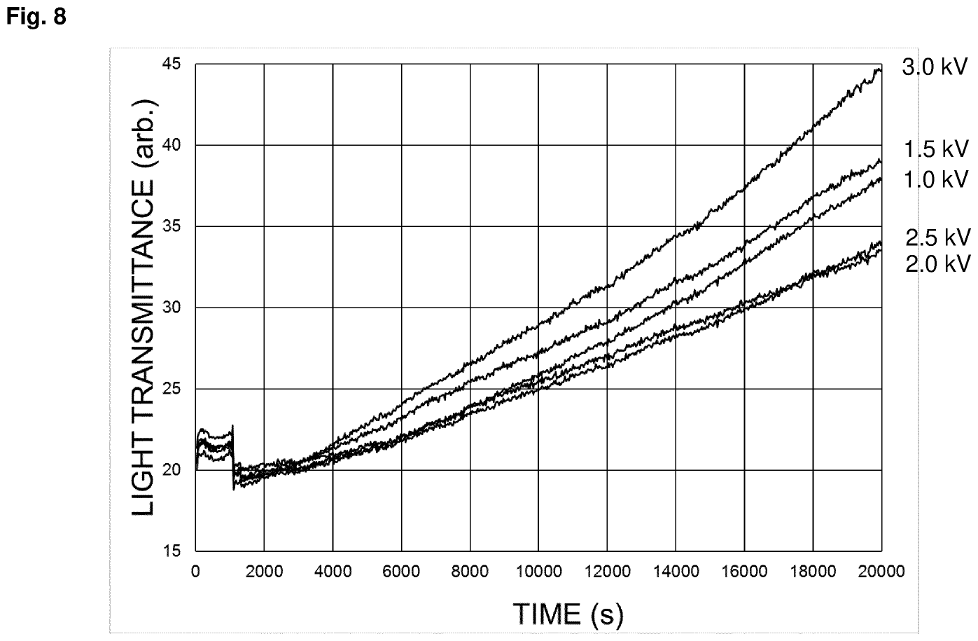

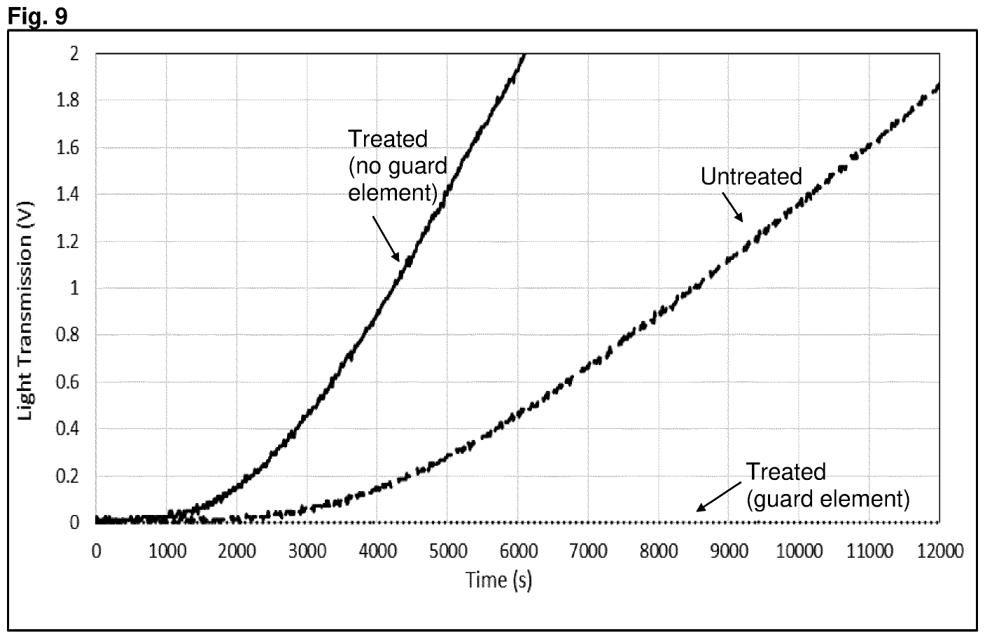

As shown in FIGS. 7 and 8, dispersions of the oxygen-plasma-treated GNPs were significantly more stable than the untreated GNPs, indicating that functionalisation of the GNPs had occurred.

In addition, there was a noticeable difference between the degree of functionalisation of the GNPs treated using the different transformers. The results for plasma-treated GNPs can be collected into two groups.

The first group, consisting of the GNPs functionalised using the 0.5 kV transformer and 3.5 kV transformer, displayed moderate stability. The second group, consisting of the GNPs functionalised using the transformers between 1.0-3.0 kV, displaying relatively higher stability. These results indicate that the GNPs of the second group have a higher degree of surface functionalisation than the first group.

The lower degree of functionalisation of the first group can be attributed to poorer efficiency of the plasma treating process. In the case of the 0.5 kV transformer, the measured voltage rating percentage was around 100%, which led to a reduction in power output from the transformer and consequently intermittent flickering of the plasma. In the case of the 3.5 kV transformer, the power source struggled to supply sufficient power to the electrode to maintain the plasma, and arcing events were detected, both of which led to the plasma intermittently cutting out. Thus, for both the 0.5 and 3.5 kV transformers, interruption of plasma production led to interruption of the surface functionalisation of the GNPs.

In contrast, in the higher functionalisation group, the transformers were able to efficiently produce plasma at the required power settings, leading to a more stable plasma, and hence a higher degree of functionalisation.

### Examples 4-6

Examples 4 to 6 were conducted to demonstrate the effect of using a guard element according to FIG. 5A on the performance of the plasma treatment apparatus described in FIG. 1 above.

### Example 4

A series of experiments were conducted to show the effect of using a guard element on the degree of functionalisation of graphitic materials.

Tests were conducted with two different types of graphitic materials: few layered graphene (FLG) and graphene nanoplatelets (GNP). Samples of each of these materials were loaded into the treatment vessel and subjected to treatment with an oxygen plasma. The conditions used during the treatment of the different materials are given in Table 3 (see below).

TABLE 3

| | Amount of | | | |
|---|---|---|---|---|
| | material | | Pressure/ | Treatment |
| | loaded/g | Power/W | mbar | time/mins |
| GNP | 520 | 70 | 0.7 | 60 |
| FLG | 130 | 70 | 0.7 | 180 |

After treatment the samples were dispersed in water, and the degree of functionalisation was assessed by monitoring light transmittance through the dispersion over time, according to the following method:

Dispersion stability analysis method
1. 10 mg of each material was added to 25 ml of deionised water in a surfactant-free vial.
2. The mixtures were agitated for 30 s to create a colloidal suspension.
3. The transmission of light through the colloid was measured over a 4-hour period.
4. Measurements were recorded by a Dispersion Stability Analyser in conjunction with Velleman data logger and PCLab 2000SE software.
5. Slower increase of light transmission over time is directly related to better dispersion stability.

Generally, 3 sets of samples were compared each time. The stability of a dispersion of untreated nanomaterials was also assessed, to serve as a control experiment. In addition, the stability of a dispersion of a sample treated using an apparatus without a guard element was also assessed. In all cases, the slower the decrease in light transmittance, the more stable the dispersion.

GNPs

FIG. 9 shows dispersions of treated (in treatment vessels with and without a guard element) and untreated GNPs. The GNPs treated in a treatment vessel with a guard element were significantly more stable than the untreated GNPs, indicating that functionalisation of the GNPs had occurred after treatment in a treatment vessel with a guard element.

The sample treated in a treatment vessel with no guard element demonstrates inferior stability than the sample of untreated GNPs and consequently, also inferior stability than the sample of GNPs treated in a treatment vessel with a guard element. The lower stability of the GNPs treated in a treatment vessel without a guard element may be attributed to the treatment process removing contaminants that prevented close particle interaction and encouraging sedimentation by agglomeration. The treatment in a treatment vessel without a guard element however, has not led to functionalisation of the GNPs due to the system continually arcing.

For the GNPs treated in a treatment vessel with a guard element it was possible to efficiently functionalize the GNPs. Dispersability was improved to the point where no measurable sedimentation was seen after 12000 s (=3 hrs 20) and the colloid blocked out all light. The dispersion stability index data for each of the GNP materials is given in Table 4 below.

TABLE 4

| Treatment type | Stability Index¹ |
|---|---|
| Treatment with guard element | 20 (+/−0.55) |
| Treatment without guard element | 6 (+/−0.55) |
| None (untreated sample) | 13 (+/−0.55) |

¹The stability index is proportional to the absorption measured through the sample after 3 hrs 20 mins.

FLG

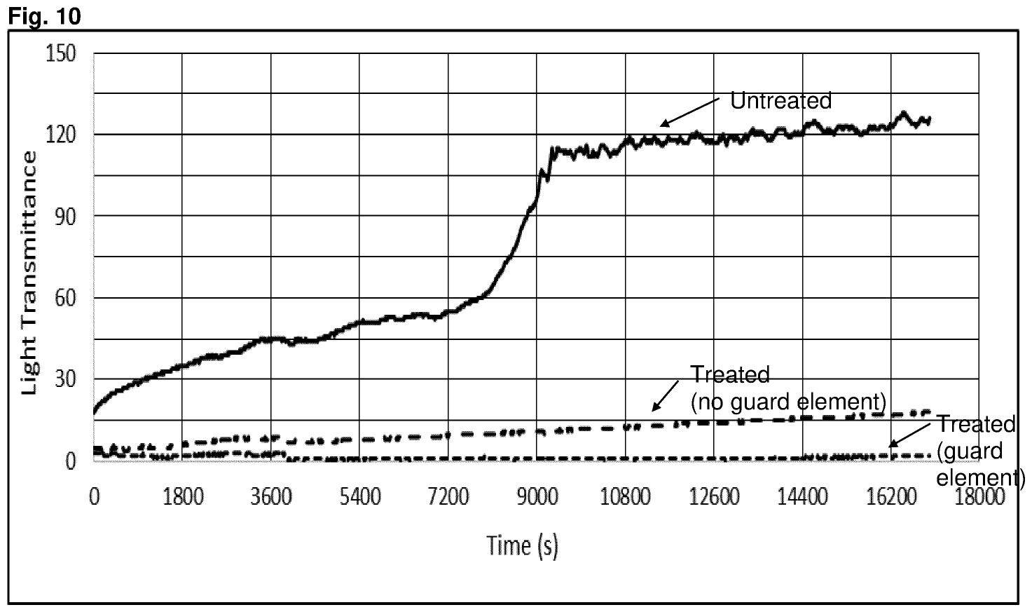

FIG. 10 shows dispersions of treated and untreated FLG materials. Both sets of treated FLG materials were more stable than the untreated FLG, indicating that functionalisation had taken place.

In addition, there was a noticeable difference between the degree of functionalisation of the FLG treated in a treatment vessel with a guard element than the FLG treated in a treatment vessel without a guard element. The sample of the FLG treated in a treatment vessel without a guard element demonstrated inferior dispersion stability than the FLG treated in a treatment vessel with a guard element. These results indicate that the FLG functionalised in a treatment vessel with a guard element had a higher degree of surface functionalisation than the sample treated in a treatment vessel without a guard element.

For the FLG functionalised in a treatment vessel with a guard element it was possible to efficiently functionalize the FLG and dispersability was improved to the point where no measurable sedimentation was seen after 17000 s (=4 hrs 40).

The light transmittance at 120 minutes for each of the FLG materials is given in Table 5 below.

TABLE 5

| | Light Transmittance |
|---|---|
| Treatment type | at 120 minutes |
| None (untreated sample) | 55 (+/−15.4) |
| Treatment without guard element | 10 (+/−15.4) |
| Treatment with guard element | 1 (+/−15.4) |

### Example 5

A series of experiments were conducted to show the effect of a guard element on the number of arcing events detected by the arc detection system.

Tests were conducted with three different types of carbon materials: GNPs, FLG and MWCNT (Multi wall carbon nanotubes). Samples of each of these materials were loaded into the treatment vessel and subjected to treatment with an oxygen-plasma. The conditions used during the treatment of the different materials are given in Table 6 (see below).

TABLE 6

| | Amount of | | | |
|---|---|---|---|---|
| | material | | Pressure/ | Treatment |
| | loaded/g | Power/W | mbar | time/mins |
| GNP | 520 | 70 | 0.7 | 60 |
| FLG | 130 | 70 | 0.7 | 180 |
| MWCNT | 130 | 70 | 0.7 | 180 |

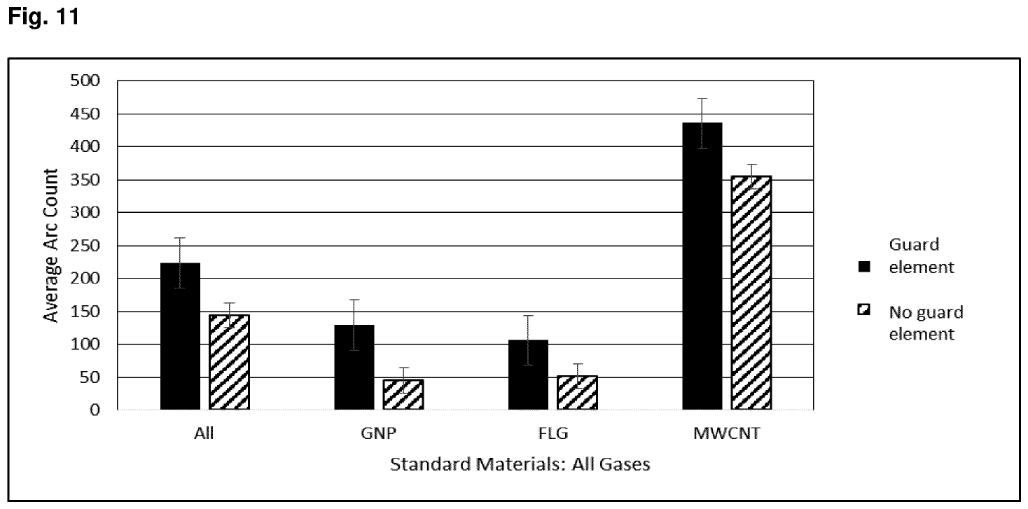

FIG. 11 shows the average number of arcs generated for each of the materials, when treated in a treatment apparatus with a guard element according to FIG. 5A and without a guard element according to FIG. 5A. Error bars show the standard error of the mean, calculated according to equation 1:

$$Standard Error of mean = \frac{StdDev}{\sqrt{n}} \qquad Equation 1$$

whereby, StdDev is the standard deviation and n is the number of runs conducted.

The power and treatment times used were the same for the tests carried out in the treatment apparatus with and without a guard element for each of the materials tested.

The numerical data for all of the runs is given in Table 7 below.

TABLE 7

| | Mean number | Number of | Standard | Standard |
|---|---|---|---|---|
| | of arcs | runs (n) | Deviation | Error |
| No guard | 223.2 | 1421 | 657.0 | 37.9 |
| element | | | | |
| Guard | 144.3 | 1413 | 398.3 | 18.9 |
| element | | | | |

These results show that for all of the materials tested (GNPs, FLG and MWCNT) fewer arcs were detected when a guard element was used.

### Example 6

A series of experiments were conducted to show the effect of using a guard element on the pressure and voltage observed inside the treatment vessel during a given treatment step.

FLG type material was loaded into the treatment vessel and subjected to treatment with an oxygen plasma.

The treatment vessel was fitted with two pressure sensors one just prior to the gas inlet (barrel pressure) and one at the gas outlet, after the filters (chamber pressure). If the chamber pressure differs from the barrel pressure this indicates that the filters are becoming blocked.

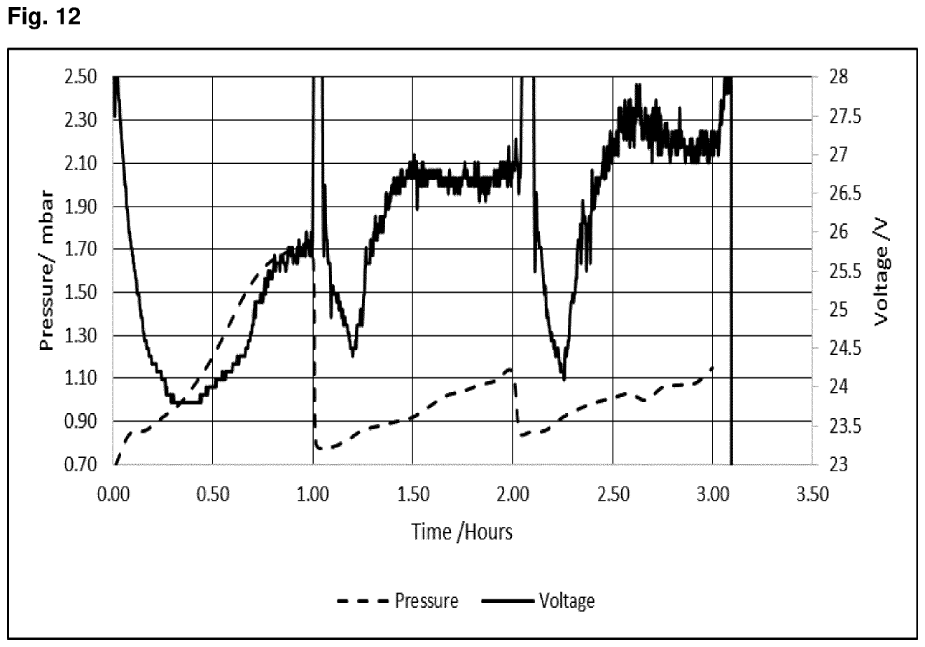

FIG. 12 shows the barrel pressure and voltage inside the reaction vessel for a system without guard elements. The chamber pressure registered at around 0.7 mbar throughout and so is omitted for clarity. The process was paused every hour and the filters were back flushed to remove any sample trapped in the filters (back flushing of filters refers to process of removing reactor barrel from chamber and agitating filters to clear built-up material).

FIG. 12 shows that the voltage increases in response to increases in the barrel pressure (generally, voltage and pressure are expected to be related according to Paschen's Law). However, discontinuity between the barrel pressure and the chamber pressure shows that there must be a partial physical barrier between the barrel and the rest of the chamber (where the chamber pressure is measured) suggesting that the chamber filters have become blocked. This is attributed to FLG clogging the filters. The voltage during the treatment step has a range of approximately 4 kV %.

Back flushing of the filters is shown to return pressure and voltage to within normal limits, this again demonstrates that the filters are clogging and hence causing the pressure in the barrel to rise. Plasma quality is known to depend on fine control of voltage and pressure during the treatment step and so clogged filters results in inferior quality plasma and hence less even functionalisation of the material being treated.

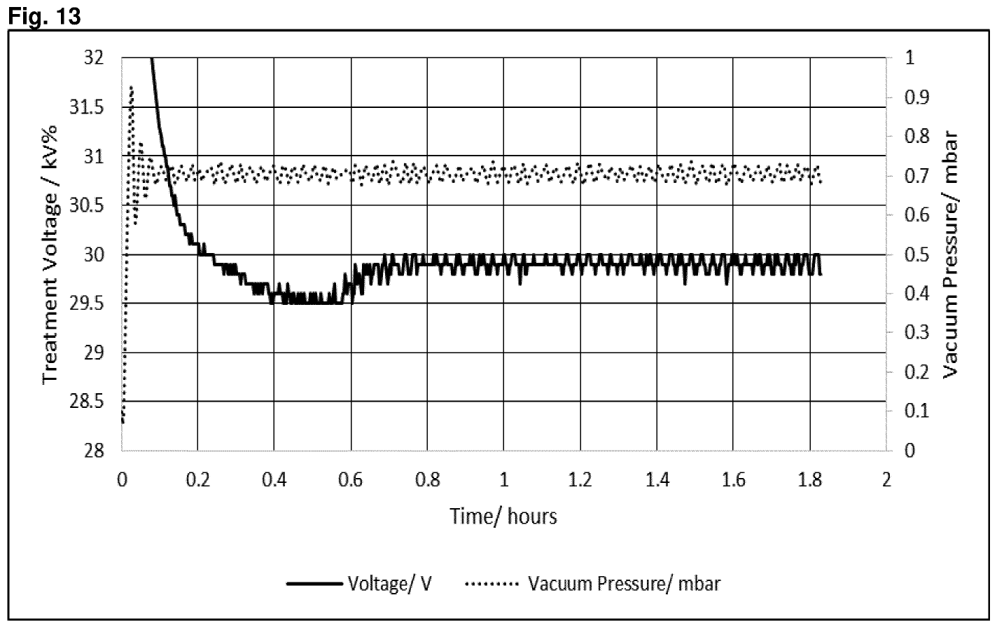

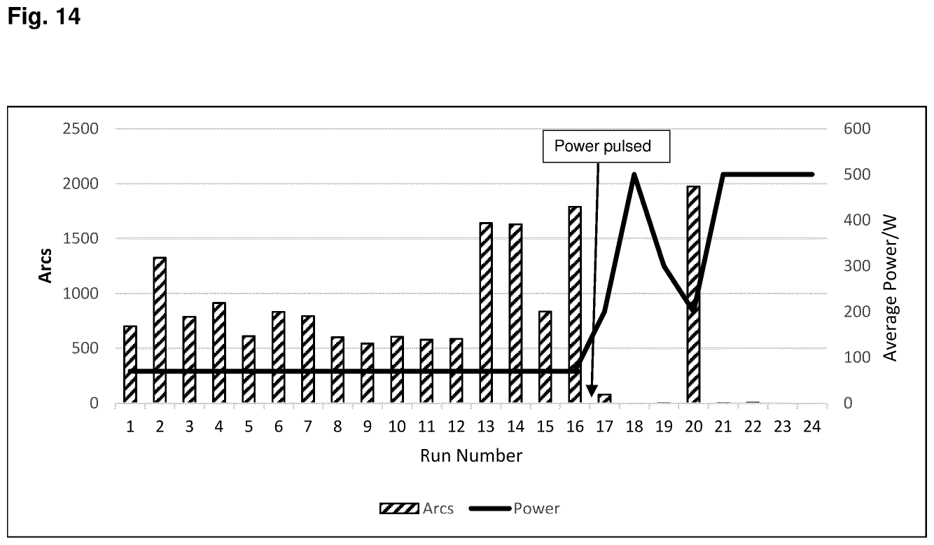

FIG. 13 shows the pressure and voltage inside the reaction vessel with a vessel filter and guard element according to FIG. 5A. The experiment was performed in the same way as described above, apart from the filters were not back flushed.

In this case the voltage is very stable, with the voltage range being within 0.5 kV % after equilibration. The barrel pressure was not measured and only chamber pressure is shown in FIG. 13, but stable voltage is taken as evidence of stable pressure. Therefore, suggesting that better quality plasma is achieved with the endplate comprising a vessel filter and guard element, which is expected to lead to more even functionalisation of the sample being treated.

### Example 7

Example 7 was conducted to demonstrate the effect of modulating the power between a higher power and a lower power on the number of arcing events detected by the arc detection system during oxygen plasma treatment.

Tests were carried out with MWCNTs in a plasma treatment vessel according to FIG. 2. Samples of MWCNTs (27 g) were loaded into the treatment vessel and subjected to treatment with an oxygen plasma at 0.7 mbar for 180 minutes (for all treatment runs shown).

Runs 1-16 and 20 were conducted without modulating the power i.e. at a constant power level. The average arc count during these tests was 922.4. During runs 17-19 and 21-24 the power was modulated according to a set pattern corresponding to a square waveform, repeated at a frequency of 500 Hz to 1000 Hz, wherein the lower power level corresponds to no power being supplied during a given treatment step and the ratio of time spent at the higher power level compared to the lower power level is at least one. During runs 17-19 and 21-24 the arc count was reduced to effectively zero. Run 20 was a control run without power modulation, helping to confirm the reduction in arc count is due to the introduction of pulsed power and not a result of any other changes that may have happened to the treatment apparatus.

The power data shows that modulating the power facilitates power increases to as much as 500 W without arcs and without the associated risk of damage to the treatment apparatus due to thermal arc formation.

### Examples 8-9

Examples 8 and 9 were conducted to demonstrate the types of functionalisation that can be achieved using the apparatus according to FIG. 2 and in particular an apparatus including a vessel filter and filter guard as in FIG. 5A.

### Example 8

Tests were conducted with FLG type materials. A sample of FLG (40 g) was loaded into the treatment vessel and subjected to treatment with a fluorination plasma, formed using CF₄ gas at 0.7 mbar with 500 W of power supplied via a 1/5 kV transformer for 180 minutes. The power was modulated during the treatment step in the same way as in example 7. The weight percentage of carbon, oxygen, nitrogen and fluorine was determined using X-Ray Photoelectron Spectroscopy (XPS). The results are given in Table 8 below.

TABLE 8

| | | Concentration/at % | | | |
|---|---|---|---|---|---|
| | | XPS | XPS | XPS | XPS |
| Sample | | C (%) | O2 (%) | N (%) | F (%) |
| Unfunctionalised | Average | 94.58375 | 5.02875 | 0.545 | 0 |
| (n = 8) | Standard | 0.993579 | 0.904647 | 0.22243 | 0 |
| | Deviation | | | | |
| Functionalised | Average | 2.715 | 68.245 | 0.285 | 28.76 |
| (n = 2) | Standard | 0.275 | 0.335 | 0.035 | 0.64 |
| | Deviation | | | | |

For all untreated FLG materials (8 repeats in total) fluorine content was confirmed to be zero.

In contrast, the treated particles demonstrate an increase in atomic percentage of fluorine of 28.76% (based on 2 repeats).

Addition of high levels of fluorine renders graphitic material hydrophobic and has been likened to ‘Teflonisation’ because the highly fluorinated polymer PTFE/Teflon is known for its intermolecular repulsion and inert nature. This opens up markets for solid lubricants, anti-fouling surfaces and PTFE fillers.

### Example 9

A sample of boron nitride (40 g) was loaded into the treatment vessel and subjected to treatment with argon gas at the conditions given in Table 9. Samples of boron nitride (40 g) were also subjected to treatment with a number of different plasma forming feedstocks, using the conditions given in Table 9. The power was held constant (not modulated) during the course of the treatment steps.

In this example a temperature controlled treatment vessel was used and the temperature was adjusted to be suitable for the different treatment types (Raw materials). For example for ammonia (NH₃) treatment temperatures of greater than 28° C. were used and for 02 temperatures of below 20° C.

The transformer setting was also adjusted for the different treatment types (raw materials) for example a lower setting was used for O₂ than for NH₃. This demonstrates that a single machine can be used to carry out a range of different functionalisation steps with a range of different raw materials. The presence of the guard elements also helps to prevent arcing during treatment with a range of different raw materials.

TABLE 9

| Treatment | Plasma | Material | Treatment |
|---|---|---|---|
| Type | Power/W | Loading/g | Time/mins |
| Raw material | N/A | N/A | N/A |
| Ar | 70 | 190 | 180 |
| COOH | 70 | 190 | 180 |
| NH₃ | 70 | 190 | 180 |
| O₂ | 70 | 190 | 180 |
| F | 70 | 190 | 180 |

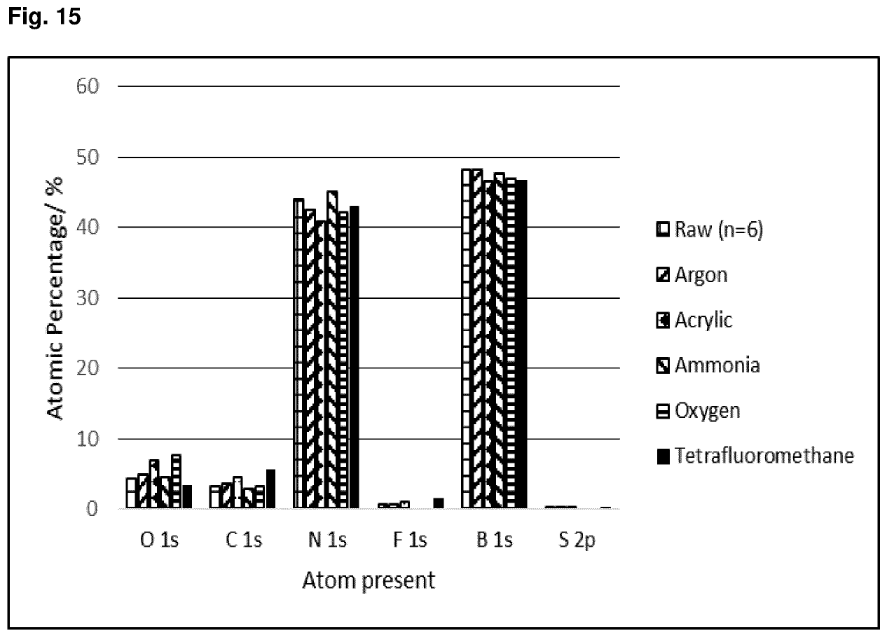

The degree of functionalisation for each of the boron nitride samples following treatment with the different plasma forming feedstocks is shown in FIG. 15.

In summary:
Oxygen (O₂) treatment increased O content by around 3.5%.
Acrylic acid (COOH) treatment increased O by 2.5%
Tetrafluoromethane (F) treatment increased F (0.7%) and C levels (2%).
Neither argon (Ar) nor ammonia (NH₃) treatment had a significant effect on the composition.

This shows that a treatment apparatus with a temperature controlled treatment vessel, guard elements and a transformer having two or more different settings allows a range of different raw materials to be functionalised.

### Example 10

The plasma treatment apparatus according to FIG. 1 incorporating a system for delivering a liquid into the treatment vessel according to FIG. 6 was used to demonstrate that the plasma treatment apparatus could be used for silane functionalisation.

Two different graphitic materials were treated under similar conditions to those used in example 8. The results of these tests are given in table 9 below.

TABLE 9

| | | | | |
|---|---|---|---|---|
| O1s | C1s | N1s | F1s | Si2p |

Material: Edge Oxidised Graphene Oxide¹

| | | | | | |
|---|---|---|---|---|---|
| Raw (Ave) | 4.86 | 94.53 | 0.61 | 0 | 0 |
| Treated | 8.87 | 90.24 | 0.59 | 0 | 0.29 |

Material: Graphene Nanoplatelets²

| | | | | | |
|---|---|---|---|---|---|
| Raw (Ave) | 4.28 | 95.35 | 0 | 0 | 0.3 |
| Treated | 6.95 | 90.29 | 0.96 | 0.05 | 1.75 |

¹The power was modulated during the treatment of the edge oxidised graphene oxide;
²The power was held at a constant level during the treatment of the graphene nanoplatelets.

Experiments demonstrated that silicon can be incorporated onto the surface of the carbon materials after treatment. This demonstrates that the liquid injection system can be used to provide plasma feedstocks to effectively functionalize the carbon materials.

### Example 11

A series of experiments were conducted to show the effect of heating on the degree of functionalisation of graphitic materials.

FLG type material was subjected to oxygen-plasma functionalisation in a treatment apparatus described in FIG. 2 above.

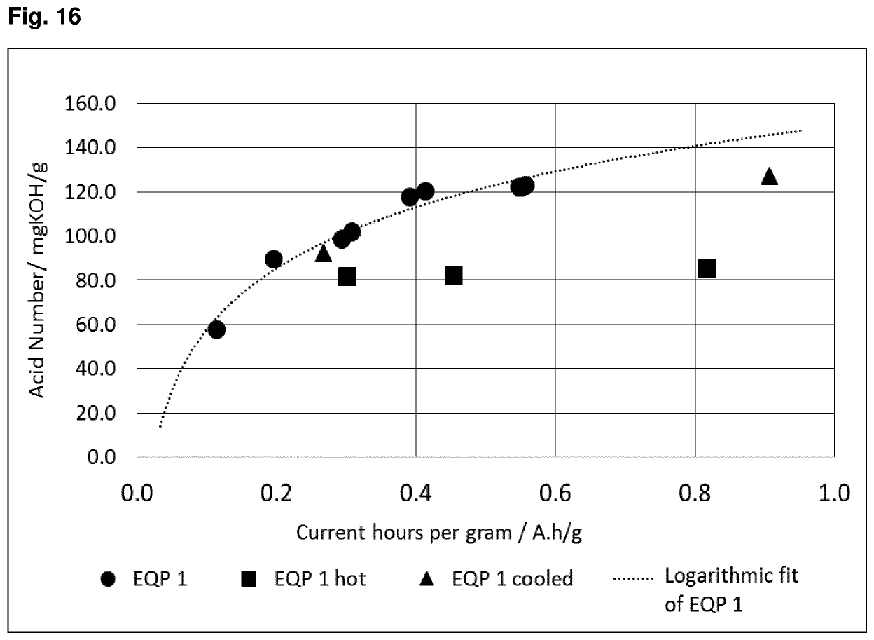

FIG. 16 shows the acid number (approximately proportional to the number of R—COOH groups on the surface of the sample) for samples after treatment against the current hours per gram of sample treated (A.h/g) used for the treatment. The acid number was determined by titration in a Mettler Toledo Autotitrator. EQP 1 corresponds to treating samples for 3 hours at various loadings and at moderate powers (insufficient to lead to significant heating, <500 W). A logarithmic trend line was plotted for EQP 1 with an R2 value of 0.9598.

For the points corresponding to EQP 1 hot the samples were treated at higher powers (>800 W, corresponding to higher currents), which generated temperatures in the barrel of >100° C. For the points corresponding to EQP 1 cooled, the materials were also treated at higher powers (>800 W), but the treatment was paused intermittently to allow the temperature of the barrel to return to ambient temperature. The results of these tests are also shown in table 10 below.

TABLE 10

| | Treatment | | | | Acid Number/ | |
|---|---|---|---|---|---|---|
| | Time/h | Power/W | Loading/g | Current/Amps | mgKOH/g | Amp · h/g |
| EQP 1 | 3 | 200 | 40 | 4.1 | 102.2 | 0.3075 |
| | 3 | 300 | 40 | 5.5 | 120.34 | 0.4125 |
| | 3 | 200 | 40 | 3.9 | 98.53 | 0.2925 |
| | 3 | 300 | 40 | 5.2 | 117.7 | 0.39 |
| | 3 | 300 | 80 | 5.208333333 | 89.7 | 0.195313 |
| | 3 | 300 | 130 | 4.901960784 | 58 | 0.113122 |
| | 3 | 500 | 40 | 7.3 | 122.46 | 0.5475 |
| | 3 | 500 | 40 | 7.42 | 123.05 | 0.5565 |
| | 3 | 500 | 40 | 7.34 | 122.46 | 0.5505 |
| EQP 1 | 3 | 804 | 40 | 10.89 | 85.46 | 0.81675 |
| hot | 3 | 1000 | 80 | 12.1 | 82.2185 | 0.45375 |
| | 1 | 1000 | 40 | 12.03 | 82 | 0.30075 |
| EQP 1 | 1 | 844 | 40 | 10.67 | 92.34 | 0.26675 |
| cooled | 3 | 1000 | 40 | 12.08 | 127.3 | 0.906 |

The values for EQP 1 hot fall below the trend line for acid number on FIG. 16; whereas the EQP1 cooled values show much better agreement with the trend line. This demonstrates that excess heat is causing the degree of functionalisation of the samples to go down, leading to lower acid numbers. Without wanting to be bound by any theory it is believed that this is a result of decarboxylation occurring due to elevated temperatures during treatment.

For the avoidance of doubt it is confirmed that in the general description above, in the usual way the proposal of general preferences and options in respect of different features and embodiments of the methods and apparatus constitutes the proposal of general combinations of those general preferences and options for the different features and embodiments, insofar as they are combinable and compatible and are put forward in the same context.

In respect of numerical ranges disclosed in the present description it will of course be understood that in the normal way the technical criterion for the upper limit is different from the technical criterion for the lower limit, i.e. the upper and lower limits are intrinsically distinct proposals.

1. A method for treating a sample using glow-discharge plasma, in an apparatus comprising a treatment vessel, an electrode, a counter-electrode, and a power supply comprising one or more transformers and having a first transformer setting and a second transformer setting, the method comprising:
a loading step, involving loading the sample into the treatment vessel;
a first treatment step involving treating the sample in a glow-discharge plasma formed within the treatment vessel by applying an electric field between the electrode and counter-electrode at the first transformer setting;
a second treatment step involving treating the sample in a glow-discharge plasma formed within the treatment vessel by applying an electric field between the electrode and counter-electrode at the second transformer setting; and
a removal step, involving removing treated sample from the treatment vessel.

2. The method for treating a sample according to claim 1, wherein the first and second transformer settings have voltage ratios of 0.5 or less, 0.45 or less, 0.4 or less, 0.35 or less, 0.3 or less, 0.25 or less, 0.2 or less, 0.15 or less, 0.1 or less, 0.05 or less, 0.025 or less, or 0.01 or less.

3. The method for treating a sample according to claim 1, wherein the first transformer setting has a different voltage ratio to the second transformer setting.

4. The method for treating a sample according to claim 3, wherein the difference between the first and second transformer voltage ratios is at least 0.01, at least 0.025, at least 0.05, at least 0.1, at least 0.15, at least 0.2, at least 0.25, at least 0.3, at least 0.35, at least 0.4, at least 0.45, or at least 0.5.

5. The method for treating a sample according to claim 1, wherein the first transformer setting has a different secondary voltage rating to the second transformer setting.

6. The method for treating a sample according to claim 5, wherein the difference between the secondary voltage ratings of the first and second transformer settings is at least 100 V, at least 200 V, at least 300 V, at least 400 V, at least 500 V, at least 750 V, at least 1 kV, at least 1.5 kV, at least 2.0 kV, at least 2.5 kV, at least 3.0 kV, at least 4.0 kV, at least 5 kV, or at least 10 kV.

7. The method for treating a sample according to claim 1, wherein the power supplied from the power supply during the first and/or second treatment step is modulated periodically between a higher power level and a lower power level.

8. The method for treating a sample according to claim 7, wherein the power is modulated between >0 W and 0 W.

9. The method for treating a sample according to claim 1, wherein the apparatus further comprises an arc detection system.

10. The method for treating a sample according to claim 1, wherein the sample is agitated within the treatment vessel during the first and/or second treatment step.

11. The method for treating a sample according to claim 10,
wherein the sample is agitated by rotating the treatment vessel about an axis in a first direction, and then rotating in the opposite direction about the same axis.

12. The method for treating a sample according to claim 10, wherein the treatment vessel is provided with an evacuation port comprising a vessel filter which is protected by a guard element, wherein the guard element blocks the sample from contacting the vessel filter during agitation, while whilst still allowing gas to flow to and through the vessel filter.

13. The method for treating a sample according to claim 12, wherein the treatment vessel is a drum capped by end plates with the vessel filter(s) provided on one or both of the end plate(s), generally spaced from the edges of the end plate so as to be placed above the level of the sample in use, wherein the guard element comprises a wall extending from the end-plate into the interior of the treatment vessel and at least partially surrounding the filter element.

14. The method for treating a sample according to claim 12, wherein the guard element is a tube extending from the end plate into the interior of the treatment vessel and surrounding the vessel filter.

15. The method for treating a sample according to claim 14, wherein the tube has a first end extending into the interior of the treatment vessel, and a second end extending to the exterior of the treatment vessel, the apparatus further comprising a guard filter disposed towards the first end of the tube, and a vessel filter disposed towards the second end of the tube.

16. The method for treating a sample according to claim 1, wherein the treatment vessel is a cylindrical drum capped with two end-plates, wherein the interior surface of the drum is made from an electronically conductive material, and the internal surface of the end plates is made from an electrically insulating material.

17. The method for treating a sample according to claim 1, wherein the apparatus has at least one electrode extending within the interior of the treatment vessel and at least one electrode shield extending within the treatment vessel between the electrode and an interior wall of the treatment vessel, wherein the electrode shield is made from an insulating material and is positioned to block arcing to said interior wall of the treatment vessel in use.

18. The method for treating a sample according to claim 1, wherein the treatment vessel is a temperature controlled treatment vessel and wherein within a given treatment step the temperature is held at a constant temperature of from about −20° C. to about 120° C.

19. The method for treating a sample according to claim 1, wherein the first and second treatment steps are functionalization steps.

20. Apparatus for treating a sample in a method as defined in claim 1, comprising a treatment vessel, an electrode, a counter-electrode, and a power supply comprising one or more transformers.

21. A method for treating a sample using glow-discharge plasma, the method comprising one or more treatment steps, wherein during the one or more treatment steps a glow discharge plasma is formed by supplying power to the treatment apparatus and wherein during the one or more treatment steps the power is modulated periodically between different power levels according to a set pattern.

22-25. (canceled)

26. The method for treating a sample according to claim 7, wherein the power is modulated at a frequency of from 500 Hz to 1000 Hz.

27. The method for treating a sample according to claim 10, wherein the sample is agitated by rotating the treatment vessel through an angle of no more than ±120°.
